(19) United States
(12) Patent Application Publication
(10) Pub. No.: US 2026/0300796 A1
(43) Pub. Date: Oct. 1, 2026

(54) METHOD FOR PERFORMING QUANTUM ERROR CORRECTION

(71) Applicant: XANADU QUANTUM TECHNOLOGIES INC., Toronto (CA)

(72) Inventors: Eric Leland SABO, Smyrna, GA (US); Benjamin Christopher IDE, Atlanta, GA (US); Lane Gabriel GUNDERMAN, Evanston, IL (US); Guillaume DAUPHINAIS, Toronto (CA); Michael John George VASMER, Toronto (CA)

(21) Appl. No.: 19/048,414

(22) Filed: Feb. 7, 2025

Related U.S. Application Data
(60) Provisional application No. 63/550,772, filed on Feb. 7, 2024.

(51) Int. Cl. G06N 10/70; H03M 13/11

(52) U.S. Cl. CPC G06N 10/70; H03M 13/118

(57) ABSTRACT

A method for constructing a quantum error correction code based on weight reduced classical code is described herein. When the weight of a row r of the classical code check matrix is above a weight threshold x, the row is replaced with a matrix M comprising a first sub-matrix and a second sub-matrix. The first sub-matrix is constructed such that the i-th column of the first sub-matrix has a weight equal to the i-th element of row r. Each column of the second submatrix having a non-zero even-numbered weight. Each row of the second sub-matrix having a weight of less than or equal to (x−w₁), w₁ being the weight of a corresponding row of the first sub-matrix. Then zeros are appended to the end of each row of check matrix besides row r, producing a weight reduced check matrix, from which a quantum error correcting code may be constructed.

### CROSS-REFERENCE TO RELATED APPLICATIONS

This application claims priority to, and the benefit of, U.S. Provisional Patent Application No. 63/550,772, filed on Feb. 7, 2024 and titled “Method for Constructing Quantum Error Correcting Codes,” the entire contents of which are incorporated by reference herein in their entirety.

### BACKGROUND OF THE INVENTION

The present disclosure is related to quantum technology, and in particular to a method and system of performing quantum error correction based on weight-reduced check matrix.

Quantum error correction (QEC) is believed to be a fundamental aspect of any large-scale fault-tolerant quantum computer. In recent years, there has been remarkable progress in realizing QEC codes on various hardware platforms.

In a widely-studied class of QEC codes called the stabilizer code, one measures parity-check operators that give partial information about errors that may have occurred on the physical qubits of the code. However, in a realistic physical environment, the act of measuring the parity-check operators is itself a noisy process. In many hardware platforms, the noise associated with measuring a parity check scales with the weight of the check, which is defined as the number of qubits that the check acts on non-trivially. The higher check weights generally correspond to deeper measurement circuits. In addition, the number of checks in which a qubit participates, known as qubit degree, is also associated with higher error as the noise in one qubit could be percolated to multiple checks. Hence, one way to find practically useful stabilizer codes is to search for stabilizer codes with low-weight parity-checks and qubit degrees, which are known as quantum low-density parity-check (qLDPC) codes.

The surface code is an example of a qLDPC code, as all of its checks have weight four and qubit-degree two. However, the surface code suffers from the drawback that it always encodes a fixed number of logical qubits, for a given topology. This low encoding rate means that, for realistic noise rates, we expect to have approximately 1000 physical qubits per logical qubit, which leads to estimates of millions of physical qubits being required for any practical largescale quantum algorithms. There exist other families of qLDPC codes with higher encoding rates than the surface code, though this often comes with slightly higher parity-check weights and the requirement of long-range connectivity.

Thus, there is a need for a method of performing quantum error correction, such as a weight reduced qLDPC code, that minimizes performance limitation due to high parity-check weights under realistic noise assumptions while retaining favourable performance metrics, such as high encoding rate.

### SUMMARY OF THE INVENTION

In one aspect, the present disclosure provides a method for performing a quantum error correction, comprising: receiving a parity check matrix H of a classical code, the parity check matrix H having p rows and n columns, n and p being positive integers; determining if a weight wᵣ of a row r of the p rows is above a target weight threshold x; when the weight wᵣ is above the target weight threshold x, reducing the weight wᵣ by: replacing the row r with a matrix M having m rows, m being a positive integer, the matrix M comprising of a first sub-matrix and a second sub-matrix, wherein: the first sub-matrix comprises n columns, an i-th column of the first sub-matrix having a weight of 1 when an i-th element of the row r is 1, i being a positive integer, and the i-th column of the first sub-matrix having a weight of 0 when the i-th element of the row r is 0; the second sub-matrix comprises (m−1) columns, each column of the (m−1) columns of the second sub-matrix having a non-zero even-numbered weight and each row of the m rows of the second sub-matrix having a weight of less than or equal to (x−w1), w1 being equal to the weight of a corresponding row of the first sub-matrix; and appending (m−1) zeros to the end of each row of H that is not row r; and performing quantum error correction based on the parity check matrix after the reducing.

In another aspect, there is provided a method for constructing a quantum error correcting code, comprising: receiving a classical code comprising a first plurality checks and a first plurality of bits; determining if a weight w_{c} of a check c of the first plurality of checks is above a target weight threshold x; when the weight w_{c} is above the target weight threshold x, reducing the weight w_{c} by replacing the check c with a second plurality of checks and adding a second plurality of bits to the classical code, wherein: each bit of the first plurality of bits is in the support of a check of the second plurality of checks when the bit of the first plurality of bits is in the support of the check c, each bit of the second plurality of bits is in the support of a non-zero even number of the second plurality of checks, and each check of the second plurality of checks has support on x or fewer bits; and performing quantum error correction based on the classical code after the reducing.

Any of the above aspects may further comprise, after the reducing and before the performing: transposing the parity check matrix H; repeating the determining and the reducing on the transposed parity check matrix; and transposing the transposed parity check matrix.

Any of the above aspects may further comprise replacing the row r with the matrix M when the weight wᵣ is greater than the weight threshold x.

In any of the above aspects, the determining and reducing may be repeated for a plurality of rows of the parity check matrix before the performing.

In any of the above aspects, the classical code may be a LDPC code.

In any of the above aspects, the weight threshold x may be equal to 3.

In any of the above aspects, an i-th element of the i-th column of the first sub-matrix may be 1 when the i-th element of the row r is 1.

In any of the above aspects, a first element of a first column of the first sub-matrix may be 1; an m-th element of an n-th column of the first sub-matrix may be 1; and an l-th element of an (l+1)-th column of the first sub-matrix may be 1 when an (l+1)-th element of the row r is 1, l being a positive integer and l≤m.

Any of the above aspects may further comprise permuting a plurality of non-zero columns of the first sub-matrix.

In any of the above aspects, the permuting may further comprise determining a permutation of a plurality of permutations of the plurality of non-zero columns that provides optimal code parameters.

In any of the above aspects, the code parameters may include code distance and encoding rate.

In any of the above aspects, a first element of a first row of the second sub-matrix may be 1; an (m−1)-th element of an m-th row of the second sub-matrix may be 1; for an integer j ranging from 2 to (m−1), when a j-th row of the first sub-matrix has a weight of 1, a k-th element and a (k+1)-th element of a j-th row of the second sub-matrix may be each equal to 1, k being equal to a number of rows of the first sub-matrix above the j-th row with a weight of 1; and when the j-th row of the first sub-matrix has a weight of 0, the j-th row of the second sub-matrix may have a weight of 0.

Any of the above aspects may further comprise, after the reducing and before the performing: transposing the first plurality of checks; repeating the determining and the reducing on the transposed plurality of checks; and transposing the transposed plurality of checks.

In any of the above aspects, the constructing may be further based on one or more additional parity check matrices.

In any of the above aspects, the determining and reducing may be repeated for each check in the first plurality of checks.

Any of the above aspects may further comprise permuting a plurality of non-zero columns of the first plurality of checks.

In any of the above aspects, the permuting may further comprise determining a permutation of a plurality of permutations of the plurality of non-zero columns that provides optimal code parameters.

### BRIEF DESCRIPTION OF DRAWINGS

Reference will now be made, by way of example, to the accompanying drawings which show example embodiments of the present disclosure, and in which:

FIGS. 1A and 1B illustrate the operation of copying on an exemplary Tanner graph;

FIGS. 2A and 2B illustrate the operation of gauging on an exemplary Tanner graph;

FIGS. 3A and 3B illustrate the operation of thickening on an exemplary Tanner graph;

FIGS. 3C and 3D illustrate the operation of choosing height on the Tanner graph of the Z stabilizers in FIG. 3A;

FIG. 4A illustrates an exemplary input graph;

FIG. 4B illustrates one possible choice of the spanning tree of the input graph in FIG. 4A;

FIG. 4C illustrates the fundamental cycle basis of the input graph in FIG. 4A;

FIG. 4D illustrates a minimum-weight cycle basis for the input graph in FIG. 4A;

FIGS. 5A-F illustrate the operation of coning on an exemplary Tanner graph;

FIGS. 6A-C illustrate the operations of the copying step, the reduced copying step, and the targeted copying step, respectively;

FIGS. 7A-D illustrate the effect of the degree of freedom in assigning a qubit to one of its copies in the repetition code;

FIG. 8 illustrates a flowchart of a method in accordance with an embodiment of the present disclosure for constructing a weight-reduced quantum error correction code;

FIG. 9 illustrates a pseudo-code Algorithm 1 that may be used to implement the one or more steps the method shown in FIG. 8;

FIGS. 10A-C illustrate a Tanner graph, and the corresponding Tanner graphs of compressed classical weight reduction and the class weight reduction, respectively;

FIG. 11 illustrates a simplified block diagram of an example embodiment of a quantum computing system in accordance with the present disclosure;

FIG. 12 illustrates a flowchart of a method in accordance with another embodiment of the present disclosure for constructing a weight-reduced quantum error correction code;

FIG. 13 illustrates Table I showing the simulation results of applying classical weight reduction method in accordance with embodiments of the present disclosure to hypergraph-product codes with some known linear codes of small size as input;

FIG. 14 illustrates Table 11 showing the simulation results of applying classical weight reduction method in accordance with embodiments of the present disclosure to a family of hypergraph-product codes listed in a known academic literature;

FIG. 15 illustrates Table Ill showing the simulation results of applying quantum weight reduction method with targqX=3 applied to small hypergraph-product codes;

FIG. 16 illustrates Table IV showing the simulation results of applying classical weight reduction method in accordance with embodiments of the present disclosure to lifted-product codes;

FIG. 17 illustrates Table V showing the simulation results of applying classical weight reduction method in accordance with embodiments of the present disclosure to hypergraph-product codes with some of the known linear codes with 14≤n≤15;

FIGS. 18A and 18B illustrate plots of simulation results of logical error rates of applying classical weight reduction method in accordance with embodiments of the present disclosure and the quantum weight reduction method to hypergraph product codes; and

FIGS. 19A and 19B illustrate plots of simulation results of logical error rates of applying classical weight reduction method in accordance with embodiments of the present disclosure and the quantum weight reduction method to lifted-product codes.

### DETAILED DESCRIPTION OF THE INVENTION

One candidate to implement the qLDPC code is the hypergraph product code, which manipulates commutation relations using algebraic or graph-theoretic techniques to convert classical codes into quantum codes. The technique of hypergraph product permits any resulting quantum code to inherit the properties of the classical code such that any LDPC classical code, after applying hypergraph product, would also yield qLDPC codes.

Let H be a parity check matrix of a classical code, the corresponding hypergraph product code can then be denoted as HGP(H). In at least one aspect of the present disclosure, there is provided a method to create a weight reduced version of HGP(H). For certain quantum computing architectures, such as measurement based photonic architectures, the qubit weight is of particular importance because the noise present in each qubit may scale roughly as

$$1 - erf ( c \sqrt{\frac{η}{n ( 1 - η )}} ) ,$$

where erf is the error function, η is the transmissivity, and n is the connectivity of a qubit in a cluster state implementing the code. In some embodiments of the present disclosure, the weight reduced version of the HGP code has maximum stabilizer weight of 6 and maximum qubit weight of 3 while maintaining the logical gates of the original hypergraph product code and at least maintaining or increasing code distance. The reduced stabilizer weight may also improve performance of the overall quantum computing architecture.

Some embodiments of the present disclosure involve operations designed to be operated or to be executed on one or more quantum computers. In further embodiments, the quantum simulation method described herein may be implemented with a synergistic hybrid approach where one or more of the steps, such as weight reduction, may be performed on one or more classical computers and operably coupled to the quantum computer(s) to instruct a network of interferometers to perform corresponding stitching (i.e. quantum entangling) of qubits and one or more detectors to perform quantum measurement in constructing the weight-reduced QEC described herein.

Section I below provides relevant background in classical and quantum coding theory. Section II describes a quantum weight-reduction method originally proposed in “Weight reduction for quantum codes” by Hastings, arXiv:1611.03790 (2016) and “Weight reduction for quantum codes” by Hastings, arXiv:2102 10030 (2023), the entire disclosure of which is incorporated herein in their entireties. The method is herein referred to as the Hastings method. The section further proposes an alternative algorithmic approach to improve the Hastings method to reduce its overhead and examine its implications for iterative coding. Construction of a weight-reduced error correction method in accordance with embodiments of the present disclosure and its application to reduce stabilizer weight in the context of quantum product codes are described in Section III. In Section IV, examples of weight-reduced codes and the results of our numerical simulations are presented.

### I. CODING THEORY AND NOTATION

For simplicity and clarity, examples and embodiments herein are described with respect to [symbol] ₂ vector spaces, although many aspects of the disclosure herein are not limited by the choice of vector space dimension and may be extended to higher dimensional fields. Dots or missing entries in matrices are assumed to be zero, and horizontal and vertical dividing lines within matrices are added throughout solely for visual convenience. The symbol 0 will be used to indicate a scalar, a vector, or a matrix, as appropriate, and should be clear from context.

Let H be a full-rank, (n−k)×n matrix. The H with respect to the standard (Euclidean) inner product [n,k,d] classical linear code C=C(H) associated with H is the subspace, orthogonal to the row space of

$$C = \{ v ∈ {𝔽}_{2}^{n} \vert {H}_{v}^{T} = 0 \} ,$$

where v=(v₁, . . . , vₙ) is thought of as a row vector and superscript “T” is the standard matrix transpose. The support of v is the set supp(v)={i|vᵢ≠0}. In this context, H is called the parity-check matrix of C and serves a role similar to the stabilizers in QEC. The minimum distance of the code is given by d=min{wt(v)|0≠v∈C}, where wt=|supp(v)| denotes the Hamming weight.

A quantum, [symbol] n,k,d [symbol] Pauli stabilizer code may be described numerically by its stabilizer matrix in symplectic form whose first n columns of which denote Pauli X operators, while the subsequent n columns denote Pauli Z operators. CSS codes can be described by two matrices, H_{X} and Hz, of n columns corresponding to the X and Z stabilizer generators, respectively, such that the stabilizer matrix is of the form H_{X}⊕H_{Z}. The inputs of a procedure acting on a set of stabilizers appear as H_{X} and H_{Z} and the outputs are H_{X} and H_{Z}. Let n_{X} and n_{Z} be the number of X and Z stabilizers, respectively, w_{X} and w_{Z} be the maximum Hamming weight of the X and Z stabilizer generators, respectively, and q_{X} and q_{Z} be the maximum Hamming weight of the columns of H_{X} and H_{Z}, respectively. The parameters q_{X} and q_{Z} are also referred to as the X- and Z-qubit degrees, respectively. For example, q_{X} denotes the maximum number of stabilizer generators that have nontrivial support on the same qubit. Note that these parameters are not inherent to the code but are relative to the specific form of the generators chosen.

Hypergraph product codes HGP(H₁,H₂) are defined as the CSS codes constructed from two parity-check matrices H₁ and H₂ with stabilizers.

$${H}_{Z} = ( {H}_{1} ⊗ I I ⊗ {H}_{2}^{T} ) ) , {H}_{Z} = ( I ⊗ {H}_{2} {H}_{1}^{T} ⊗ I ) \qquad ( 1 )$$

If C(Hᵢ) has parameters [nᵢ,kᵢ,dᵢ] and

$$C ( {H}_{i}^{T} )$$

has parameters

$$[ {m}_{i} , {k}_{i}^{T} , {d}_{i}^{T} ] ,$$

where

$${k}_{i}^{T} and {d}_{i}^{T}$$

are the dimension and distance of C(H^{T}), respectively, then HGP(H₁,H₂) has parameters

$$\text{?} {n}_{1} {n}_{2} + {m}_{1} {m}_{2} , {k}_{1} {k}_{2} + {k}_{1}^{T} {k}_{2}^{T} , min ( {d}_{1} , {d}_{2} , {d}_{1}^{T} , {d}_{2}^{T} ) \text{?} \qquad ( 2 )$$

### Let

$${R}_{ℓ} = \frac{{𝔽}_{2} [ x ]}{{x}^{ℓ} - 1}$$

be a polynomial quotient ring. A circulant matrix is a square matrix specified by the first row or column, where each subsequent row (column) is cyclically shifted to the right (down) by one index. An element g(x)=g₀+g₁x+ . . . + [symbol] ∈ [symbol] is associated with the [symbol] × [symbol] circulant matrix, [symbol] (g(x)), the first column of which is given by coefficients of g(x). This is referred to as the lift of g(x). The lift of a matrix A∈M_{m×n}( [symbol] ) with elements in [symbol] is the matrix [symbol] (A)∈ [symbol] constructed by replacing each element of A with its lift. The matrix A is called the base (or weight or protograph) matrix of the lift and [symbol] is the lift size. For example, for [symbol] =2,

$$A = ( \begin{matrix}1 & x \\ 0 & 1 + x\end{matrix} ) , 𝔹 ( A ) = ( \begin{matrix}𝔹 ( 1 ) & 𝔹 ( x ) \\ 𝔹 ( 0 ) & 𝔹 ( 1 + x )\end{matrix} ) = ( \begin{matrix}1 & 0 & 0 & 1 \\ 0 & 1 & 1 & 0 \\ 0 & 0 & 1 & 1 \\ 0 & 0 & 1 & 1\end{matrix} ) \qquad ( 3 )$$

Although typically defined by the form of its generator matrix, the present disclosure defines a quasi-cyclic code to be the linear code that is defined by the parity-check matrix H=B(A). Quasi-cyclic lifted product codes are a generalization of hypergraph product codes based on quasi-cyclic codes. Let A₁∈M_{m1×n}( [symbol] ) and A₂∈M_{m2×n2}( [symbol] ) be base matrices and define

$${A}_{X} = ( {A}_{1} ⊗ I I ⊗ {A}_{2} ) , {A}_{Z} = ( I ⊗ {A}_{2}^{T} {A}_{1}^{T} ⊗ I ) , \qquad ( 4 )$$

where the transpose of g(x) is determined by the transpose of its lift: g^{T}(x)=g₀+ [symbol] + . . . + [symbol] The lifted product code LP(A₁,A₂) is the CSS code with parity-check matrices H_{X}= [symbol] (A_{X}) and H_{Z}= [symbol] (A_{Z}). The length of the code is n= [symbol] (n₁m₂+n₂m₁) but, to the best knowledge of the inventors, there are currently no general formulas for k and d; however, lifted product codes often have superior parameters to hypergraph product codes of similar size as have been shown in known works.

The Tanner graph representation of linear codes and stabilizer codes are used herein. Check nodes will be denoted by rectangles and variable nodes by circles. For CSS codes, open rectangles will denote X-stabilizers and filled-in rectangles Z-stabilizers.

Here, a chain complex C is defined to be an ordered sequence of vector spaces {Cᵢ} over [symbol] ₂ with maps ∂ᵢ between each ordered pair {Cᵢ₋₁,Cᵢ} such that ∂ᵢ∘∂ᵢ₊₁=0:

$$… \to {C}_{i + 1} {\to }^{{\partial }_{i + 1}} {C}_{i} {\to }^{{\partial }_{i}} {C}_{i - 1} \to … .$$

Only chain complexes with a finite number of vector spaces are of interest. A chain complex with l spaces is called an [symbol] -term chain complex. Since ∂ᵢ∘∂ᵢ₊₁=0, the image im(∂ᵢ₊₁) is a subset of the kernel ker(∂ᵢ), e.g. img(∂ᵢ₊₁)⊆ker(∂ᵢ). A sequence is said to be exact at Cᵢ if img(∂ᵢ₊₁)=ker(∂ᵢ) and is said to be exact if it is exact at each Ct. The i-th homology group is defined as Hᵢ(·)=ker(∂ᵢ)/im(∂ᵢ₊₁). The letter H will also be used for parity-check and stabilizer matrices, but the context in which it is used will be clear. The dual of a chain complex is a cochain complex

$$… \to {C}_{i + 1} {\to }^{{δ}_{i + 1}} {C}_{i} {\to }^{{δ}_{i}} {C}_{i - 1} \to … .$$

The corresponding dual of the homology groups are the cohomology groups Hᵢ(·)=kerδᵢ₊₁/imδᵢ. Since the standard basis is assumed in the present disclosure,

$${δ}_{i} = {\partial }_{i}^{T} .$$

A natural correspondence exists between codes and chain complexes. Let

$$H ∈ {𝔽}_{2}^{n - k \times n}$$

be a parity-check matrix of an [n,k,d]-linear code. Then the code can be expressed as a chain complex

$${𝔽}_{2}^{n} {\to }^{H} {𝔽}_{2}^{n - k} . \qquad ( 5 )$$

It follows that any diagram comprising of a single map vacuously satisfies the definition of a chain complex.

Consider an [symbol] n,k,d [symbol] CSS code generated by n_{Z} independent Z stabilizers given by the matrix H_{Z} and n_{X} X stabilizers given by H_{X}. Since

$${H}_{Z}^{T} {H}_{X} = 0 ,$$

this can be treated as the chain complex:

$${𝔽}_{2}^{{n}_{Z}} {\to }^{{H}_{Z}^{T}} {𝔽}_{2}^{n} {\to }^{{H}_{X}} {𝔽}_{2}^{{n}_{Z}} , \qquad ( 6 )$$

With the qubits in the center. Conversely, a CSS code can be derived from any two consecutive boundary maps, setting

$${H}_{Z}^{T} = {\partial }_{i + 1}$$

and H_{X}=∂ᵢ. The Z logical operators commute with the X stabilizers (ker H_{X}) and are not Z stabilizers

$$( {imH}_{Z}^{T} = rowspace ( {H}_{Z} ) ) ,$$

which make them elements of the first homology group H₁. The cochain of

$${𝔽}_{2}^{{n}_{Z}} {←}^{{H}_{Z}} {𝔽}_{2}^{n} {←}^{{H}_{X}^{T}} {𝔽}_{2}^{{n}_{X}}$$

provides the X logicals

$${H}_{1} ( \cdot ) = {kerH}_{Z} / {imH}_{X}^{T} .$$

### II. IMPROVED HASTINGS WEIGHT REDUCTION METHOD

Earlier referenced works by Hastings provides a quantum weight-reduction method that generally can be divided into four steps:
(1) Copying—to reduce q_{X};
(2) Gauging—to reduce w_{X};
(3) Thickening and choosing heights—to reduce q_{Z}; and
(4) Coning—to reduce w_{Z}.

Each of the above steps are examined and improvements with respect to one or more of the steps are described thereafter. It is noted that the examples and figures provided are contrived to demonstrate a specific concept and are not meant to represent good stabilizer codes. Applying these operations to practical codes produces large matrices and complicated Tanner graphs, from which may be difficult to discern the underlying structure.

### A. Copying

Let variables without a tilde refer to the input to copying and let variables with a tilde refer to its output. The goal of copying is to reduce q_{X} to a threshold value, for example being at most three. The step starts by making q_{X} number of copies of each qubit, which means adding q_{X}−1 new qubits (all initialized to zero) per original qubit. The numerical value of each original qubit is not copied to the new qubits:

$$( {v}_{1} {v}_{2} … {v}_{n} ) ↦ ( {v}_{1 , 1} … {v}_{1 , qX} \vert {v}_{2 , 1} … {v}_{2 , qX} \vert … \vert {v}_{n , 1} … {v}_{n , qX} ) ,$$

where the vertical lines are included as a visual aid to identify each block of q_{X} qubits. For every X stabilizer of length n, a new stabilizer of length q_{X} n is created such that for every vᵢ in the support of the stabilizer, one of {v_{i,1}, . . . , v_{i,q}_{_{X}}} receives the numerical value of vᵢ. If one stabilizer utilizes the qubit v_{i,j}, another stabilizer would be precluded from using the same qubit. For example, valid copies of the stabilizer (1 1 1 1 1 1) with q_{X}=3 include

$$( 100 \vert 100 \vert 100 \vert 100 \vert 100 \vert 100 ) \qquad ( 7 )$$

$$and$$

$$( 010 \vert 001 \vert 100 \vert 001 \vert 100 \vert 010 ) \qquad ( 8 )$$

As vectors, these are equivalent up to qubit permutations. For simplicity, the matrix columns are filled from left to right as in Equation (7). Suppose that Equation (7) is used and that (1 1 0 0 1 1) is another stabilizer. Then,

$$( 100 \vert 010 \vert 000 \vert 000 \vert 010 \vert 010 )$$

Is not a valid copy, because the qubit v_{1,1} is already used by the first stabilizer. Note that every original X stabilizer is kept, although now in a permuted form.

In addition to the copied stabilizers, (q_{X}−1)n new X stabilizers are added to link the copies of vᵢ such that they collectively function similar to the original single qubit. These are weight two and of the form v_{i,j} v_{i,j+1} for 1≤j≤q_{X-1}. Note that these are not constrained by the “validity” concept required for the previous stabilizers. For example,

$$( 110 \vert 000 \vert 000 \vert 000 \vert 000 \vert 000 ) ,$$

$$( 011 \vert 000 \vert 000 \vert 000 \vert 000 \vert 000 ) ,$$

$$( 000 \vert 110 \vert 000 \vert 000 \vert 000 \vert 000 ) ,$$

$$( 000 \vert 011 \vert 000 \vert 000 \vert 000 \vert 000 ) ,$$

$$⋮$$

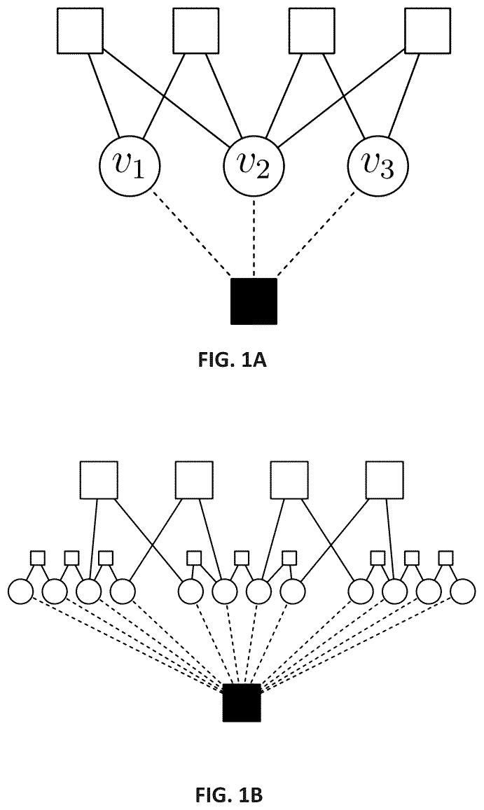

This imposes a classical repetition code on the copies as shown in FIGS. 1A and 1B. In FIGS. 1A and 1B, the open (white) squares represent X stabilizers, the filled (black) squares represent the Z stabilizers, and the circles are qubits. In FIG. 1A, the maximum column weight is q_{X}=4 at vertex v₂, e.g. there are 4 X stabilizers connected to the v₂ qubit. FIG. 1B shows the copied variables (the circles) in the repetition codes of FIG. 1A, which would have labels v_{1,1}, v_{1,2}, V_{1,3}, V_{1,4}, V_{2,1} . . . , and so on from left to right. As can be seen in FIG. 1B the maximum column weight is now 3 as none of the copied variables has more than 3 X stabilizers connections.

The commutativity with the Z stabilizers is maintained on every copy by putting the numerical value at vᵢ at v_{i,j} for all 1≤j≤q_{X}. For example, if (1 0 1 0 1 0) is a Z stabilizer, then for q_{X}=3, the new Z stabilizer is

$$( \begin{matrix}1 & 1 & 1 \vert 0 & 0 & 0 \vert 1 & 1 & 1 \vert 0 & 0 & 0 \vert 1 & 1 & 1 \vert 0 & 0 & 0 )\end{matrix}$$

This comes at the cost of increasing the weight of the Z stabilizer w_{Z}, which will be dealt with in subsequent steps described in more detail more.

It follows from above that ñ=q_{X}n, ñ_{X}=n_{X}+(q_{X}−1)n, ñ_{Z}=n_{Z}, \tilde{w}_{X}=w_{X}, \tilde{q}_{X}=min{q_{X},3}, \tilde{w}_{Z}=qₓw_{Z}, and \tilde{q}_{Z}=q_{Z}. It further follows that \tilde{k}=ñ−ñ_{X}−ñ_{Z}=n−n_{X}−n_{Z}=k. Traditionally, the dimension is computed by counting the number of logical operators, but since the dimension is already known, k independent operators that commute with the stabilizers and are therefore logical operators can be derived. A Z-logical operator must commute with both the old and new X stabilizers. The old X stabilizers are supported on qubits v_{i,1} for 1≤i≤n. An fixed i in the overlap between an old X stabilizer and an old Z logical would render the old stabilizers not to commute with the new X stabilizer v_{i,1}v_{i,2}. The only way to address this is to extend the support of the Z stabilizer to all of the copied qubits {v_{i,1}, . . . , vᵢ,q_{X}}. The new Z logicals are thus of the form z⊗(1 . . . 1), where z is a Z-logical operator of the input code and the all-ones vector has length q_{X}. The X logicals of the input code still commute with the new Z stabilizers on the bits v_{i,1}. This gives \tilde{d}_{X}=d_{X} and \tilde{d}_{Z}=q_{X}d_{Z}. The foregoing results are summarized in Lemma 1 for convenience.

### Lemma 1

Let variables without a tilde refer to the input to copying and let variables with a tilde refer to the output of copying. Then,

$$\tilde{n} = {q}_{X} n \qquad ( a )$$

$${\tilde{n}}_{X} = {n}_{X} + ( {q}_{X} - 1 ) n \qquad ( b )$$

$${\tilde{n}}_{Z} = {n}_{Z} \qquad ( c )$$

$$\tilde{k} = k \qquad ( d )$$

$${\tilde{w}}_{X} = {w}_{X} \qquad ( e )$$

$${\tilde{q}}_{X} = min \{ {q}_{X} , 3 \} \qquad ( f )$$

$${\tilde{w}}_{Z} = {q}_{X} {w}_{Z} \qquad ( g )$$

$${\tilde{q}}_{Z} = {q}_{Z} \qquad ( h )$$

$${\tilde{d}}_{X} = {d}_{X} \qquad ( i )$$

$${\tilde{d}}_{Z} = {q}_{X} {d}_{Z} \qquad ( j )$$

Graphically, copying replaces each variable node in the Tanner graph with a repetition code of X stabilizers protecting against phase errors. For example, the Tanner graph of FIG. 1A is transformed to that of FIG. 1B. The manner in which the edges from the check nodes are attached to the repetition codes corresponds to the choice in placing vᵢ in its copies. In particular, the ordering of the original stabilizers induces a potential permutation of the edges, the implications of which is discussed in more detail below.

### B. Gauging

The goal of gauging is to reduce w_{X} to less than or equal to the threshold value, such as 3 used in the previous example, without increasing q_{X}. Consider an X stabilizer of weight w>3 with support on qubits labeled by {v₁, . . . , v_{w}}. For each such stabilizer, gauging introduces w−3 new qubits,

$$\{ {v}_{1}^{′} , … , {v}_{w - 3}^{′} \} .$$

These are in addition to any new qubits introduced by copying described herein. The input X stabilizer is replaced by the new X stabilizers with supports

$$\{ {v}_{1} , {v}_{2} , {v}_{1}^{′} \} , \{ {v}_{3} , {v}_{1}^{′} , {v}_{2}^{′} \} , \{ {v}_{4} , {v}_{2}^{′} , {v}_{3}^{′} \} , … , \{ {v}_{w - 2} , {v}_{w - 4}^{′} , {v}_{w - 3}^{′} \} , \{ {v}_{w - 1} , {v}_{w - 3}^{′} , {v}_{w}^{′} \} ) \qquad ( 9 )$$

To express the above in matrix form, assume, without loss of generality, that the support of the stabilizer is permuted to the first w qubits. Then,

$$( 10 )$$

$$( \begin{matrix}{v}_{1} & … & {v}_{w} & & & \\ 1 & … & 1 & 0 & … & 0\end{matrix} ) ↦ ( \begin{matrix}{v}_{1} & {v}_{2} & {v}_{3} & … & \text{?} & \text{?} & {v}_{w} & & \text{?} & \text{?} & … & \text{?} & \text{?} \\ 1 & 1 & & & & & & … & 1 & & & & \\ & & 1 & & & & & … & 1 & 1 & & & \\ & & & ⋱ & & & & … & & & ⋱ & & \\ & & & & 1 & & & … & & & & 1 & 1 \\ & & & & & 1 & 1 & … & & & & & 1\end{matrix} ) \text{?}$$

$$\text{?} \text{indicates text missing or illegible when filed}$$

where the column of dots represents qubits not in the support of the current stabilizer. Note that the right-hand side is

$${H}_{w - 2}^{T} ,$$

where the transpose

$${H}_{ℓ} = ( \begin{matrix}1 & 1 & & & & \\ & 1 & 1 & & & \\ & & ⋱ & & & \\ & & & 1 & 1 & \\ & & & & 1 & 1\end{matrix} ) \qquad ( 11 )$$

is a parity-check matrix for the [ [symbol] , 1, [symbol] ] classical repetition code. The left-hand side of the matrix (portion before the “ . . . ”) in Equation (10) has support on the original qubits. The new (primed) qubits are not used by any other X stabilizer, leaving the right-hand side (portion after the “ . . . ”) as the direct sum

$${⊕}_{i} {H}_{{w}_{i} - 2}^{T} ,$$

where wᵢ is the weight of the i-th reduced X stabilizer.

At this point, the Z stabilizers only have support on the original qubits and may no longer commute with the rows of Equation (10). Consider the w−2 new rows of a weight-reduced X stabilizer, where the new stabilizers are arranged in the order of Equation (10). If the j-th Z stabilizer anticommutes with the product of new X stabilizers 1 to m for i∈{1, . . . , w−3}, then set the m-th new column of the j-th row of H_{Z} to one, where the new columns are those that were introduced when applying gauging to the original X stabilizer. An alternative method to construct commuting Z stabilizers is described herein in more detail.

It follows from above that ñ and ñ_{X} increase by wᵢ−3 for each wᵢ>3 while ñ_{Z}=n_{Z} and, hence, \tilde{k}=k as well as that \tilde{w}_{X}=min{w_{X},3}, \tilde{q}_{X}=q_{X}, \tilde{w}_{Z}≥w_{Z}, and \tilde{q}_{Z}≥q_{Z}. The old X logical operators (appended with zeros for the new primed qubits) still commute with the new Z stabilizers; however, \tilde{d}_{X} could decrease. For an element of ker \tilde{H}_{Z} with non-zero support on the new qubits that is not an X stabilizer, known works have shown that the matrices

$${H}_{{w}_{i} - 2}^{T}$$

can be row reduced to the identity (and a zero row) and may be used to remove the logical operator's support on the new qubits. This could lead to a lower-weight logical representative than the logical operators of the input code. The Z distance is at least d_{Z} as shown in more detail herein. The results of gauging are summarized in Lemma 2 for convenience. Note that the input to gauging may be the output of copying if the operations are chained, in which case the input variables are the tilded output variables in Lemma 1.

### Lemma 2

Let variables without a tilde refer to the input to gauging and let variables with a tilde refer to the output of gauging. Then,

$$\tilde{n} = n + {\sum }_{{n}_{X}} \{ \begin{matrix}{w}_{i} - 3 , & if {w}_{i} > 3 \\ 0 , & else\end{matrix} \leq n + {n}_{X} ( {w}_{i} - 3 ) \qquad ( a )$$

$$( b ) {\tilde{n}}_{X} = {n}_{X} + {\sum }_{{n}_{X}} \{ \begin{matrix}{w}_{i} - 3 , & if {w}_{i} > 3 \\ 0 , & else\end{matrix} \leq {n}_{X} + {n}_{X} ( {w}_{i} - 3 ) \qquad ( b )$$

$${\tilde{n}}_{Z} = {n}_{Z} \qquad ( c )$$

$$\tilde{k} = k \qquad ( d )$$

$${\tilde{w}}_{X} = min ( {w}_{X} , 3 ) \qquad ( e )$$

$${\tilde{q}}_{X} = {q}_{X} \qquad ( f )$$

$$( g ) {\tilde{w}}_{Z} \geq {w}_{Z} \qquad ( g )$$

$$( h ) {\tilde{q}}_{Z} \geq {q}_{Z} \qquad ( h )$$

$${\tilde{d}}_{Z} \geq {d}_{Z} \qquad ( i )$$

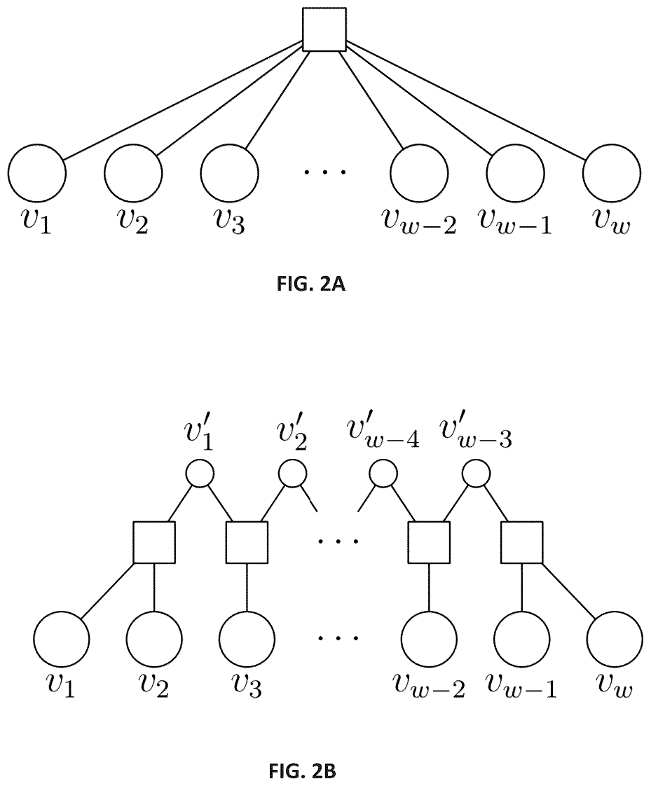

FIGS. 2A and 2B graphically illustrate the operation of gauging. FIG. 2A shows an example input Tanner graph with an X stabilizer (square) supported by qubits (circles) v₁ to v_{w}. Gauging transforms the X stabilizers of the Tanner graph from FIG. 2A into that of FIG. 2B with new X stabilizers supported by one or more of the original qubits as well as the newly introduced qubits

$${v}_{1}^{′} to {v}_{w - 3}^{′} .$$

The matrices

$${H}_{w - 2}^{T}$$

induce a repetition code on the check nodes instead of the variable nodes. It is noted that the Hasting's method treats copying and gauging as a single operation. In the present disclosure, the two concepts are separated and the new qubits resulting from copying are called “copied” qubits and the new qubits resulting from gauging are called “new” qubits.

### C. Thickening and Choosing Heights

The goal of thickening is to increase the code distance d_{X} and the goal of choosing heights is to reduce the number of Z stabilizers that each qubit participates in as indicated by the Z qubit degree q_{Z}. Independently, thickening is commonly referred to as (a special case of) distance balancing, using the chain complexes

$$𝒜 : {𝔽}_{2}^{{n}_{Z}} {\to }^{{H}_{Z}^{T}} {𝔽}_{2}^{n} {\to }^{{H}_{Z}} {𝔽}_{2}^{{n}_{X}} ,$$

$$ℬ : {𝔽}_{2}^{ℓ - 1} {\to }^{{H}_{ℓ}^{T}} {𝔽}_{2}^{ℓ - 1} ,$$

where [symbol] is defined in Equation (11).

The tensor product of these two chains [symbol] ⊗ [symbol] can be determined as follows:

Let

$$𝒜 : … \to {A}_{i + 1} \text{?} {A}_{i - 1} \to … ,$$

$$ℬ : … \to {B}_{i + 1} \text{?} {B}_{i} \text{?} {B}_{i - 1} \to …$$

$$\text{?} \text{indicates text missing or illegible when filed}$$

be chain complexes with vector spaces over the same field. Then, [symbol] ⊗ [symbol] is defined to have vector spaces

$${( 𝒜 ⊗ ℬ )}_{n} = \begin{matrix}⊕ \\ i + j = n\end{matrix} {𝒜}_{i} ⊗ {ℬ}_{j}$$

and maps

$${\partial }_{n}^{𝒜 ⊗ ℬ} = \begin{matrix}⊕ \\ i + j = n - 1\end{matrix} \text{?} ⊗ {I}_{{B}_{j}} + {I}_{{A}_{i}} ⊗ {\partial }_{j + 1}^{ℬ} , \qquad ( A1 )$$

$$\text{?} \text{indicates text missing or illegible when filed}$$

where I is the identity map on the appropriate space. Concrete examples relevant to this work are the product of a three-term and a two-term chain complex and the product of two three-term chain complexes. For the former, let

$$𝒜 \text{:} {A}_{2} {\to }^{{\partial }_{2}^{𝒜}} {A}_{1} {\to }^{{\partial }_{1}^{𝒜}} {A}_{0} ,$$

$$ℬ \text{:} {B}_{1} {\to }^{{\partial }_{1}^{ℬ}} {B}_{0} .$$

The product A⊗B is often drawn as

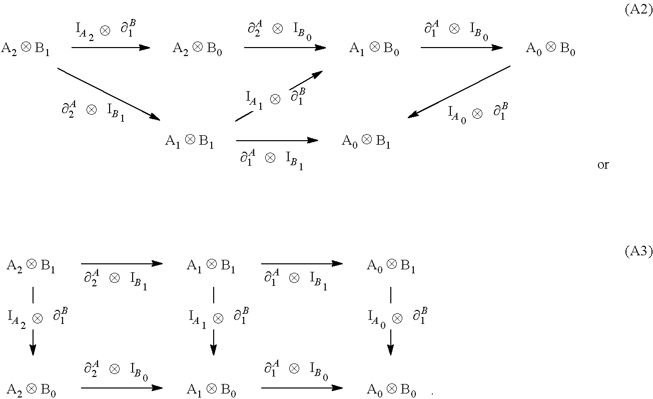

Using A(3), vertical and horizontal maps may be defined as,

$${\partial }_{i}^{v} and {\partial }_{i}^{h} ,$$

respectively, such that

$${\partial }_{i}^{v} ∘ {\partial }_{i + 1}^{v} = {\partial }_{i}^{h} ∘ {\partial }_{i + 1}^{h} = 0$$

and that

$${\partial }_{i}^{v} and {\partial }_{i}^{h}$$

commute. Then every purely vertical chain and every purely horizontal chain form a valid chain complex.

Diagram Equation (A3) is called a double complex. Equation (A1) describes the chain complex formed from collapsing the double complex into the four-term sequence

$$𝒞 = 𝒜 ⊗ ℬ \text{:} {C}_{3} {\to }^{{\partial }_{3}^{𝒞}} {C}_{2} {\to }^{{\partial }_{2}^{𝒞}} {C}_{1} {\to }^{{\partial }_{1}^{𝒞}} {C}_{0} , \qquad ( A4 )$$

$$with$$

$${C}_{3} = {A}_{2} ⊗ {B}_{1} ,$$

$${C}_{2} = ( {A}_{2} ⊗ {B}_{0} ) ⊕ ( {A}_{1} ⊗ {B}_{1} ) ,$$

$${C}_{1} = ( {A}_{1} ⊗ {B}_{0} ) ⊕ ( {A}_{0} ⊗ {B}_{1} ) ,$$

$${C}_{0} = {A}_{0} ⊗ {B}_{0} .$$

Note that the above expressions can be discerned from Equation (A2) by collapsing each vertically aligned element with a direct sum or by taking diagonal lines through Equation (A3). This is called the total complex.

The maps of the total complex [Equation (A1)] are

$${\partial }_{3}^{𝒞} = ( {I}_{{A}_{2}} ⊗ {\partial }_{1}^{ℬ} ) ⊕ ( {\partial }_{1}^{𝒜} ⊗ {I}_{{B}_{1}} ) ,$$

$${\partial }_{2}^{𝒞} = ( {\partial }_{2}^{𝒜} ⊗ {I}_{{B}_{0}} + {I}_{{A}_{1}} ⊗ {\partial }_{1}^{ℬ} ) ⊕ ( {\partial }_{1}^{𝒜} ⊗ {I}_{{B}_{1}} ) ,$$

$${\partial }_{1}^{𝒞} = {\partial }_{1}^{𝒜} ⊗ {I}_{{B}_{0}} + {I}_{{A}_{0}} ⊗ {\partial }_{1}^{ℬ} .$$

To derive explicit matrix representations of these maps, the + and ⊕ therein are ignored and the derivation begins with first principles:

$${\partial }_{3}^{C}$$

takes basis vectors of C₃ to basis vectors of C₂. The basis elements of C₂ can be grouped by those spanning the space A₂⊗B₀, then those spanning A₁⊗B₁. Assuming that we want θ₃^{C} to act by left multiplication, a matrix representation can be organized as

$${A}_{2} ⊗ {B}_{1}$$

$$Mat ( {\partial }_{3}^{𝒞} ) = \begin{matrix}{A}_{2} ⊗ {B}_{0} \\ {A}_{1} ⊗ {B}_{1}\end{matrix} ( \begin{matrix}{I}_{{A}_{2}} ⊗ {\partial }_{1}^{ℬ} \\ {\partial }_{2}^{𝒜} ⊗ {I}_{{B}_{1}}\end{matrix} ) , \qquad ( A5 )$$

where the row and column labels are added for convenience. Similarly,

$${A}_{2} ⊗ {B}_{0} {A}_{1} ⊗ {B}_{1}$$

$$Mat ( {\partial }_{2}^{𝒞} ) = \begin{matrix}{A}_{1} ⊗ {B}_{0} \\ {A}_{0} ⊗ {B}_{1}\end{matrix} ( \begin{matrix}{\partial }_{2}^{𝒜} ⊗ {I}_{{B}_{0}} & {I}_{{A}_{1}} ⊗ {\partial }_{1}^{ℬ} \\ 0 & {\partial }_{1}^{𝒜} ⊗ {I}_{{B}_{1}}\end{matrix} ) , \qquad ( A6 )$$

$${A}_{1} ⊗ {B}_{0} {A}_{0} ⊗ {B}_{1}$$

$$Mat ( {\partial }_{1}^{𝒞} ) = {A}_{0} ⊗ {B}_{0} ( \begin{matrix}{\partial }_{1}^{𝒜} ⊗ {I}_{{B}_{0}} & {I}_{{A}_{0}} ⊗ {\partial }_{1}^{ℬ}\end{matrix} ) . \qquad ( A7 )$$

Note that the ordering of the basis vectors in the rows of

$$Mat ( {\partial }_{i}^{𝒞} )$$

must be consistent with the ordering of the columns of

$$Mat ( {\partial }_{i - 1}^{𝒞} ) .$$

If given a different field, it would be necessary to define the maps to be

$${\partial }_{n}^{𝒜 ⊗ ℬ} = {⊕}_{i + j = n - 1} {\partial }_{i + 1}^{A} ⊗ {I}_{{B}_{j}} + {( - 1 )}^{i} {I}_{{A}_{i}} ⊗ {\partial }_{j + 1}^{B}$$

to achieve the required cancellation of terms.

The same procedure shown above may be applied to derive the tensor product of two three-term chain complexes:

$$𝒜 \text{:} {A}_{2} {\to }^{{\partial }_{2}^{𝒜}} {A}_{1} {\to }^{{\partial }_{1}^{𝒜}} {A}_{0} ,$$

$$ℬ \text{:} {B}_{2} {\to }^{{\partial }_{2}^{ℬ}} {B}_{1} {\to }^{{\partial }_{1}^{ℬ}} {B}_{0} ,$$

$$𝒞 = 𝒜 ⊗ ℬ \text{:} {C}_{4} {\to }^{{\partial }_{4}^{𝒞}} {C}_{3} {\to }^{{\partial }_{3}^{𝒞}} {C}_{2} {\to }^{{\partial }_{2}^{𝒞}} {C}_{1} {\to }^{{\partial }_{1}^{𝒞}} {C}_{0} ,$$

$${C}_{4} = {A}_{2} ⊗ {B}_{2} ,$$

$${C}_{3} = ( {A}_{2} ⊗ {B}_{1} ) ⊕ ( {A}_{1} ⊗ {B}_{2} ) ,$$

$${C}_{2} = ( {A}_{2} ⊗ {B}_{0} ) ⊕ ( {A}_{1} ⊗ {B}_{1} ) ⊕ ( {A}_{0} ⊗ {B}_{2} ) ,$$

$${C}_{1} = ( {A}_{1} ⊗ {B}_{0} ) ⊕ ( {A}_{0} ⊗ {B}_{1} ) ,$$

$${C}_{0} = {A}_{0} ⊗ {B}_{0}$$

$${A}_{2} ⊗ {B}_{2}$$

$$Mat ( {\partial }_{4}^{𝒞} ) = \begin{matrix}{A}_{2} ⊗ {B}_{1} \\ {A}_{1} ⊗ {B}_{2}\end{matrix} ( \begin{matrix}{I}_{{A}_{2}} ⊗ {\partial }_{2}^{ℬ} \\ {\partial }_{2}^{𝒜} ⊗ {I}_{{B}_{2}}\end{matrix} ) ,$$

$${A}_{2} ⊗ {B}_{1} {A}_{1} ⊗ {B}_{2}$$

$$Mat ( {\partial }_{3}^{𝒞} ) = \begin{matrix}{A}_{2} ⊗ {B}_{0} \\ {A}_{1} ⊗ {B}_{1} \\ {A}_{0} ⊗ {B}_{2}\end{matrix} ( \begin{matrix}{I}_{{A}_{2}} ⊗ {\partial }_{1}^{ℬ} & 0 \\ {\partial }_{1}^{𝒜} ⊗ {I}_{{B}_{1}} & {I}_{{A}_{1}} ⊗ {\partial }_{2}^{ℬ} \\ 0 & {\partial }_{1}^{𝒜} ⊗ {I}_{{A}_{2}}\end{matrix} ) ,$$

$${A}_{2} ⊗ {B}_{0} {A}_{1} ⊗ {B}_{1} {A}_{0} ⊗ {B}_{2}$$

$$Mat ( {\partial }_{2}^{𝒞} ) = \begin{matrix}{A}_{1} ⊗ {B}_{0} \\ {A}_{0} ⊗ {B}_{1}\end{matrix} ( \begin{matrix}{\partial }_{1}^{𝒜} ⊗ {I}_{{B}_{0}} & {I}_{{A}_{1}} ⊗ {\partial }_{1}^{ℬ} & 0 \\ 0 & {\partial }_{1}^{𝒜} ⊗ {I}_{{B}_{1}} & {I}_{{A}_{0}} ⊗ {\partial }_{2}^{ℬ}\end{matrix} ) ,$$

$${A}_{1} ⊗ {B}_{0} {A}_{0} ⊗ {B}_{1}$$

$$Mat ( {\partial }_{1}^{𝒞} ) = {A}_{0} ⊗ {B}_{0} ( \begin{matrix}{\partial }_{1}^{𝒜} ⊗ {I}_{{B}_{0}} & {I}_{{A}_{0}} ⊗ {\partial }_{1}^{ℬ}\end{matrix} ) .$$

The homology of the total complex is given by the Künneth formula,

$${H}_{k} ( 𝒜 ⊗ ℬ ) ≅ {⊕}_{i + j = k} ( {H}_{i} ( 𝒜 ) ⊗ {H}_{j} ( ℬ ) ) . \qquad ( A8 )$$

Consider the total complex shown in Equation (A4), where the chain A is the CSS code in accordance with Equation (6) and the chain B is the classical repetition code of the form shown in Equations (5) and (11). Consider the CSS code as determined by the two right-hand maps. By Equation (A8), the Z logical operators of this code are

$${H}_{1} ( 𝒞 ) = ( {H}_{1} ( 𝒜 ) ⊗ {H}_{0} ( ℬ ) ) ⊕ ( {H}_{0} ( 𝒜 ) ⊗ {H}_{1} ( ℬ ) ) .$$

To compute the homology of [symbol] , it is extended by zero on both sides as:

$$0 \to {𝔽}_{2}^{ℓ - 1} {\to }^{{H}^{T}} {𝔽}_{2}^{ℓ - 1} \to 0 \qquad ( A9 )$$

Then, H₁( [symbol] )=ker H^{T}=0 and

$${H}_{0} ( ℬ ) = {𝔽}_{2}^{ℓ} / im {H}^{T}$$

is the space of all vectors modulo even-weight vectors. This has two cosets: the coset of all even-weight vectors and the coset of all odd-weight vectors. The latter is generated by any weight-one vector. The logical operators are therefore of the form a⊗b, where a∈H₁( [symbol] ) is a Z logical operator of the original code and b∈H⁰( [symbol] ), which has minimum weight d_{Z}×1. For the X logical operators, the Künneth formula is applied to the dual of Equation (A9). Then

$${H}_{1} ( ℬ ) = {𝔽}_{2}^{ℓ - 1} / im H = 0$$

as rank H= [symbol] −1 and H⁰( [symbol] )=ker H is the length [symbol] all-ones vector. Hence, X logical operators are of the form a⊗b, where a∈H₁( [symbol] ) is an X logical operator of the original code and b∈H⁰( [symbol] ). The X distance therefore increases to d_{X}× [symbol] .

The hypergraph product from Equation (1) is the tensor product

$$\begin{matrix}𝒜 : {𝔽}_{2}^{{n}_{1}} {\to }^{{H}_{1}} {𝔽}_{2}^{{m}_{1}} , \\ ℬ : {𝔽}_{2}^{{m}_{2}} {\to }^{{H}_{2}^{T}} {𝔽}_{2}^{{n}_{2}} , \\ C = 𝒜 ⊗ ℬ : {𝔽}_{2}^{{n}_{1}} ⊗ {𝔽}_{2}^{{m}_{2}} {\to }^{{\partial }_{2}} ( {𝔽}_{2}^{{n}_{1}} ⊗ {𝔽}_{2}^{{n}_{2}} ) ⊕ ( {𝔽}_{2}^{{m}_{2}} ⊗ {𝔽}_{2}^{{m}_{1}} ) {\to }^{{\partial }_{1}} {𝔽}_{2}^{{m}_{1}} ⊗ {𝔽}_{2}^{{n}_{2}} ,\end{matrix}$$

Where H₁ and H₂ are parity-check matrices of classical linear codes and

$${\partial }_{2} = ( \begin{matrix}{I}_{{n}_{1}} ⊗ {H}_{2}^{T} \\ {H}_{1} ⊗ {I}_{{m}_{2}}\end{matrix} ) , {\partial }_{1} = ( \begin{matrix}{H}_{1} ⊗ {I}_{{n}_{2}} & {I}_{{m}_{1}} ⊗ {H}_{2}^{T}\end{matrix} ) .$$

Extending the chains on both sides by zero and applying Equation (A8), the Z and X logicals are of the form

$$\begin{matrix}( {kerH}_{1} ⊗ {𝔽}_{2}^{{n}_{2}} / {im H}_{2}^{T} ) ⊕ ( {𝔽}_{2}^{{n}_{1}} / {im H}_{1} ⊗ {kerH}_{2}^{T} ) \\ and \\ ( {𝔽}_{2}^{{n}_{1}} / {im H}_{1}^{T} ⊗ {kerH}_{2} ) ⊕ {kerH}_{1}^{T} ⊗ {𝔽}_{2}^{{n}_{2}} / {im H}_{2}^{T} ) ,\end{matrix}$$

respectively.

Hence, [symbol] ⊗ [symbol] provides:

$${C}_{3} {\to }^{{\partial }_{3}} {C}_{2} {\to }^{{( {\tilde{H}}_{Z} )}^{T}} {C}_{1} {\to }^{{\tilde{H}}_{X}} {C}_{0}$$

Where the code is described by stabilizer matrices of Equation (A7) and the transpose of Equation (A6):

$${\tilde{H}}_{X} = ( {H}_{X} ⊗ \begin{matrix}{I}_{ℓ} & {I}_{{n}_{X}} ⊗\end{matrix} {H}_{ℓ}^{T} ) , {\tilde{H}}_{Z} = ( \begin{matrix}{H}_{Z} ⊗ {I}_{ℓ} & 0 \\ {I}_{n} ⊗ {H}_{ℓ} & {H}_{X}^{T} ⊗ {I}_{ℓ - 1}\end{matrix} ) , \qquad ( 12 )$$

and has distances \tilde{d}_{X}=d_{X} and \tilde{d}_{Z}=d_{Z}. The thickening step can be used to counteract the decrease in the X distance that gauging may have caused. In addition to \tilde{H}_{X} and \tilde{H}_{Z}, there is a third matrix based on Equation (A5),

$${\partial }_{3} = ( \begin{matrix}{I}_{{n}_{Z}} ⊗ {H}_{ℓ}^{T} \\ {H}_{Z}^{T} ⊗ {I}_{ℓ - 1}\end{matrix} ) , \qquad ( 13 )$$

which satisfies

$${\tilde{H}}_{Z}^{T} {\partial }_{3} = 0.$$

This implies that some of the Z stabilizers may be redundant, with linear dependencies determined by ∂₃. Note that

$${I}_{{n}_{Z}} ⊗ {H}_{ℓ}^{T} = {⊕}_{i = 1}^{{n}_{Z}} {H}_{ℓ}^{T} .$$

hⱼ of H_{Z} corresponds to a block in

$${⊕}_{i = 1}^{{n}_{Z}} {H}_{ℓ}^{T}$$

and the set of stabilizers (hᵢ⊗ [symbol] 0). The block-diagonal structure of

$${⊕}_{i = 1}^{{n}_{Z}} {H}_{ℓ}^{T}$$

implies that the [symbol] stabilizers in hⱼ⊗I [symbol] are related via [symbol] −1 constraints. Since these stabilizers are the cause of the potentially high column weights, removing the redundant stabilizers can help lower q_{Z}. The decision on which row of (hⱼ⊗ [symbol] 0) to keep is referred to as choosing heights. Herein, the height is represented by a length-n_{Z} vector, the j-th element of which is an integer between 1 and l specifying which row of (hⱼ⊗ [symbol] 0) is to be kept.

When a different height is chosen for two different rows of H_{Z}, the resulting two rows in \tilde{H}_{Z} have no qubits in common, in which case a suitable height selection and a sufficient amount of thickening may reduce q_{Z}. In some cases, choosing [symbol] =n_{Z} and heights=(1, . . . , n_{Z}) ensures a column weight of one within the block and therefore q_{Z}=3 at the cost of extra qubits. A greedy algorithm can be used when [symbol] <n_{Z} to choose heights that satisfy certain parameters such as a target q_{Z}. The properties of the resulting code depend highly on the choice of [symbol] and heights.

It follows from above that ñ= [symbol] n+( [symbol] −1)n_{X}, ñ_{X}= [symbol] n_{X}, \tilde{w}_{X}=w_{X}+2, \tilde{q}_{X}=max{q_{X},2}, and \tilde{w}_{Z}=max{w_{Z},q_{X}+2}. Before choosing heights, ñ_{Z}= [symbol] n_{Z}+( [symbol] −1)n and \tilde{q}_{Z}=max{w_{X},q_{Z}+2}. The logical operators are given by the Künneth formula in Equation (A8) as:

$$\begin{matrix}{H}_{1} ( C ) = ( {H}_{1} ( 𝒜 ) ⊗ {H}_{0} ( ℬ ) ) ⊗ ( {H}_{0} ( 𝒜 ) ⊗ {H}_{1} ( ℬ ) ) \\ = {H}_{1} ( 𝒜 ) ⊗ {H}_{0} ( ℬ )\end{matrix} ,$$

from which it follows that \tilde{k}=dim Hᵢ( [symbol] )=dim H₁( [symbol] ) dim H₀( [symbol] )=k×1. Neither the dimension nor the logicals are affected by removing redundant stabilizers. The result of the thickening step is summarized in Lemma 3 for convenience. Note that the input to thickening and choosing heights may be the output of copying then gauging if the operations are chained, in which case the input variables are the tilded variables in Lemma 2.

### Lemma 3

Let variables without a tilde refer to the input to thickening and choosing heights and let variables with a tilde refer to its output. then,

$$\tilde{n} = ℓ n + ( ℓ - 1 ) {n}_{X} \qquad ( a )$$

$${\tilde{n}}_{X} = ℓ {n}_{X} \qquad ( b )$$

$${\tilde{n}}_{Z} \leq ℓ {n}_{Z} + ( ℓ - 1 ) n \qquad ( c )$$

$$\tilde{k} = k \qquad ( d )$$

$${\tilde{w}}_{X} = {w}_{X} + 2 \qquad ( e )$$

$${\tilde{q}}_{X} = max \{ {q}_{X} , 2 \} \qquad ( f )$$

$${\tilde{w}}_{Z} = max \{ {w}_{Z} , {q}_{X} + 2 \} \qquad ( g )$$

$${\tilde{q}}_{Z} \leq max \{ {w}_{X} , {q}_{Z} + 2 \} \qquad ( h )$$

$${\tilde{d}}_{X} = ℓ {d}_{X} \qquad ( i )$$

$${\tilde{d}}_{Z} = {d}_{Z} \qquad ( j )$$

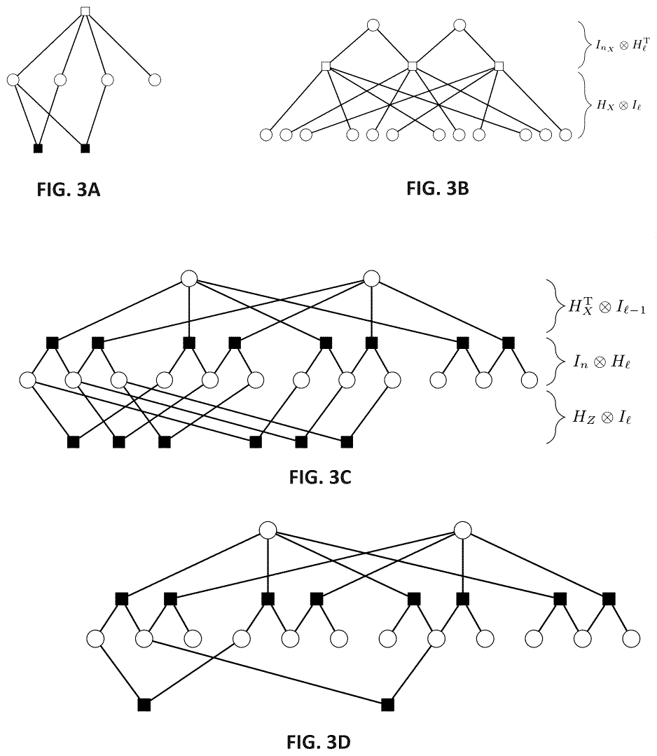

Graphically, recall that the Tanner graph has a variable node for each column (qubit) and a check node for each row (stabilizer). For the X stabilizers, there are variable nodes for each column of Iₙ_{_{X}}⊗ [symbol] and separate variable nodes for each column of H_{X}⊗ [symbol] , both of which are connected to the same check nodes. The Tanner graph of [symbol] is simply the Tanner graph of [symbol] with the variable and check nodes (columns and rows) switched. The term Iₙ_{_{X}}⊗ [symbol] makes n_{X} identical and unconnected copies of the Tanner graph of [symbol] . The term H_{X}⊗ [symbol] is equivalent to [symbol] ⊗H_{X} up to row and column permutations but connects the copies of H_{X} in a different pattern. The Z stabilizers are similar but now there is an extra set of check nodes for H_{Z}⊗ [symbol] acting on the same variable nodes as Iₙ⊗Hₗ. An example is given in FIGS. 3A-D. In FIG. 3A, the Tanner graph of exemplary stabilizers

$${H}_{X} = ( \begin{matrix}1 & 1 & 1 & 1\end{matrix} ) , {H}_{Z} = ( \begin{matrix}1 & 1 & 0 & 0 \\ 1 & 0 & 1 & 0\end{matrix} )$$

are depicted with the X stabilizer on top (white square) and the two Z stabilizers on the bottom (black squares). The effects of applying thickening to the X stabilizer in FIG. 3A is shown in FIG. 3B. It is noted that the Z stabilizers after the thickening step is omitted for clarity. FIG. 3C illustrates the effect of applying thickening to the Z stabilizers in FIG. 3A with the X stabilizers omitted for clarity. In FIG. 3D the effect of choosing heights=(1,2) on FIG. 3C is shown. As can be discerned from FIG. 3D, the X stabilizers remain unchanged. The Tanner graph for the full example code comprises the stabilizers shown in both FIGS. 3B and 3D.

### D. Coning

To illustrate the need for coning, consider the set of stabilizer generators for the 15-qubit quantum Reed-Muller code QRM(4):

$$\begin{matrix}{H}_{X} = ( \begin{matrix}1 & . & 1 & . & 1 & . & 1 & . & 1 & . & 1 & . & 1 & . & 1 \\ . & 1 & 1 & . & . & 1 & 1 & . & . & 1 & 1 & . & . & 1 & 1 \\ . & . & . & 1 & 1 & 1 & 1 & . & . & . & . & 1 & 1 & 1 & 1 \\ . & . & . & . & . & . & . & 1 & 1 & 1 & 1 & 1 & 1 & 1 & 1\end{matrix} ) , \\ {H}_{Z} = ( \begin{matrix}1 & . & 1 & . & 1 & . & 1 & . & 1 & . & 1 & . & 1 & . & 1 \\ . & 1 & 1 & . & . & 1 & 1 & . & . & 1 & 1 & . & . & 1 & 1 \\ . & . & . & 1 & 1 & 1 & 1 & . & . & . & . & 1 & 1 & 1 & 1 \\ . & . & . & . & . & . & . & 1 & 1 & 1 & 1 & 1 & 1 & 1 & 1 \\ . & . & 1 & . & . & . & 1 & . & . & . & 1 & . & . & . & 1 \\ . & . & . & . & 1 & . & 1 & . & . & . & . & . & 1 & . & 1 \\ . & . & . & . & . & 1 & 1 & . & . & . & . & . & . & 1 & 1 \\ . & . & . & . & . & . & . & . & . & 1 & 1 & . & . & 1 & 1 \\ . & . & . & . & . & . & . & . & . & . & . & 1 & 1 & 1 & 1 \\ . & . & . & . & . & . & . & . & 1 & . & 1 & . & 1 & . & 1\end{matrix} ) ,\end{matrix} \qquad ( 14 )$$

which has (w_{X}=8, q_{X}=4, w_{Z}=8, q_{Z}=10). The application of copying, gauging, and then thickening and choosing heights with [symbol] =3, heights=(2, 1, 2, 1, 2, 3, 1, 3, 3, 1) as described above generates the sequence of parameters (w_{X},q_{X},w_{Z},q_{Z}) as follows:

$$( 8 , 4 , 8 , 10 ) {\to }^{copying} ( 8 , 3 , 32 , 10 ) {\to }^{gauging} ( 3 , 3 , 43 , 10 ) {\to }^{thick \& height} ( 5 , 3 , 43 , 5 )$$

Any attempt to reduce w_{Z} using a second round of gauging applied to the Z stabilizers worsens the parameters to (w_{X}=85, q_{X}=22, w_{Z}=3, q_{Z}=5). The step of coning, by using the mapping cone described below, serves to reduce w_{Z} while preserving w_{X}, q_{X}, and q_{Z}.

To understand the concept of mapping cone, consider two chain complexes [symbol] and [symbol] :

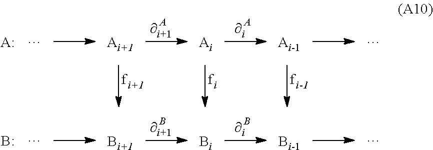

The maps fᵢ are called chain maps and they are required that the chain maps are homomorphisms that commute with the other maps, e.g.,

$${\partial }_{i + 1}^{ℬ} ( {f}_{i + 1} ( a ) ) = {f}_{i} ( {\partial }_{i + 1}^{𝒜} ( a ) )$$

for α∈Aᵢ₊₁. The mapping cone is defined to be the chain complex with spaces cone (f)ᵢ=Aᵢ⊕Bᵢ₊₁. This can be shown graphically as,

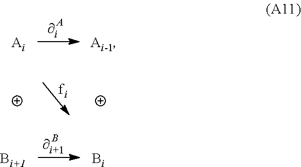

The maps ∂ᵢ:cone(f)ᵢ→cone(f)ᵢ₋₁ are

$$Mat ( {\partial }_{i} ) = \begin{matrix}{A}_{i - 1} \\ {B}_{i}\end{matrix} \begin{matrix}\begin{matrix}{A}_{i} & {B}_{i + 1}\end{matrix} \\ ( \begin{matrix}{\partial }_{i}^{𝒜} & 0 \\ {f}_{i} & {\partial }_{i + 1}^{ℬ}\end{matrix} )\end{matrix} ,$$

Note that in nonbinary fields, the first column should receive a minus sign or, equivalently, fᵢ should be replaced with (−1)ⁱfᵢ.

From the mapping cone, there is provided the short exact (split) sequence 0→Aᵢ₋₁→cone(f)ᵢ→Bᵢ→0, which reduces the long exact sequency on homology (via the snake lemma) to:

$${H}_{k + 1} ( cone ( f ) ) \to {H}_{k} ( 𝒜 ) \to {H}_{k} ( ℬ ) \to {H}_{k} ( cone ( f ) ) \qquad ( A12 )$$

In view of the above, an overview of the coning step, including the variables, spaces, and maps needed, how they are connected, and how they will be used to create new stabilizers, is provided.

A Z stabilizer to be reduced, Zᵢ, is selected and remove it from H_{Z} to create

$${H}_{Z}^{( r )} .$$

Then, the code is treated as a chain complex in the standard way,

$$ℬ : {C}_{2} {\to }^{{H}_{Z}^{( r )}} {C}_{1} {\to }^{{H}_{X}} {C}_{0}$$

with

$${C}_{2} = {𝔽}_{2}^{{n}_{Z} - 1} , {C}_{1} = {𝔽}_{2}^{n} , and {C}_{0} = {𝔽}_{2}^{{n}_{X}} .$$

Next, define a new chain complex [symbol] ᵢ:Qᵢ→Xᵢ→ [symbol] ᵢ, where

$${A}_{1} = {Q}_{i} = {𝔽}_{2}^{\vert supp ( {Z}_{i} ) \vert} ,$$

A₀=Xᵢ is derived from the overlap of Zᵢ with the X stabilizers and A₋₁= [symbol] ᵢ is constructed, if necessary, based on Qᵢ and Xᵢ, to ensure that no new logical operators are introduced with support only on the new qubits. These two chain complexes will be connected with appropriate chain maps f⁽ⁱ⁾,

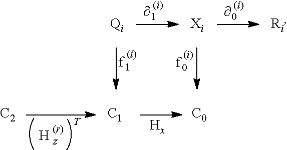

which induces the mapping cone:

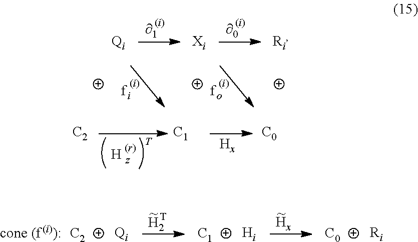

### With

$${\tilde{H}}_{X} = ( \begin{matrix}{\partial }_{0}^{( i )} & \\ {f}_{0}^{( i )} & {H}_{X}\end{matrix} ) , {\tilde{H}}_{Z} = ( \begin{matrix}{( {\partial }_{1}^{( i )} )}^{T} & {( {f}_{1}^{( i )} )}^{T} \\ & {H}_{Z}^{( r )}\end{matrix} ) \qquad ( 16 )$$

The mapping cone in Equation (15) is for a fixed i. The generalized case for m stabilizers to be weight reduced may be given by repeating the process on

$${H}_{Z}^{( r )}$$

with the next row to be removed. Alternatively, they can all be reduced at once via

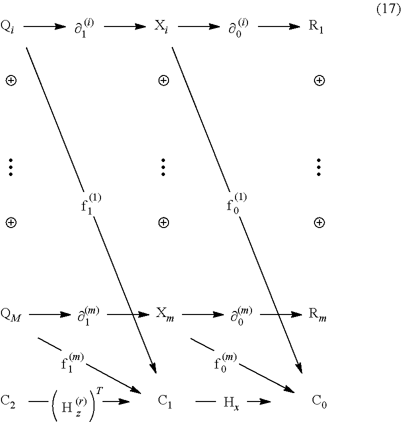

and

$${\tilde{H}}_{X} = ( \begin{matrix}{\partial }_{0}^{( 1 )} & & & \\ & ⋱ & & \\ & & {\partial }_{0}^{( m )} & \\ {f}_{0}^{( 1 )} & … & {f}_{0}^{( m )} & {H}_{X}\end{matrix} ) , {\tilde{H}}_{Z} = ( \begin{matrix}{( {\partial }_{1}^{( 1 )} )}^{T} & & & {( {f}_{1}^{( 1 )} )}^{T} \\ & ⋱ & & ⋮ \\ & & {( {\partial }_{1}^{( m )} )}^{T} & {( {f}_{1}^{( m )} )}^{T} \\ & & & {H}_{Z}^{( r )}\end{matrix} ) . \qquad ( 18 )$$

The \tilde{H}_{X} and \tilde{H}_{Z} in Equation (18) commute by definition of the chain complex. If all Z stabilizers need to be reduced, then

$${H}_{Z}^{( r )}$$

and C₂ will be empty. There may be several degrees of freedom in constructing the stabilizers in Equation (18) and the final parameters of the code are highly dependent on the choices made.

Since coning may be consider the more complex step, the following examples are described to illustrate the operation of coning. First, the following parameters that appear in the examples are defined. Let Zᵢ=(z₁, . . . , zₙ) be a Z-stabilizer generator the weight of which needs to be reduced. Define Qᵢ to be the vector space

$${𝔽}_{2}^{\vert supp ( {Z}_{i} ) \vert} .$$

There is a natural map of the standard basis of Qᵢ to all weight-one patterns of

$${𝔽}_{2}^{n}$$

contained in the support of Zᵢ,

$${f}_{1}^{( i )} : {Q}_{i} \to {C}_{1} :$$

if the k-th element of supp(Zᵢ) is zₚ, then

$${f}_{1}^{( i )}$$

maps the k-th elementary basis element of Qᵢ to the p-th elementary basis element of

$${𝔽}_{2}^{n} .$$

In other words, let Qᵢ={q₁, . . . , qₙ}, where nᵢ=|supp(Zᵢ)| and qₐ<qₐ₊₁ for all a. Then, an n×nᵢ matrix representation of

$${f}_{1}^{( i )}$$

has maximum row and column weights equal to one, which constrains w_{Z} and q_{Z} in Equation (18):

$${( {f}_{1}^{( i )} )}_{a , b} = {δ}_{a , {q}_{b}} . \qquad ( 19 )$$

### Example 1

Assume Zᵢ=(1, 0, 0, 1, 1, 0, 0, 1). Then supp(Zᵢ)=[1, 4, 5, 8] and

$${Q}_{i} = {𝔽}_{2}^{4} .$$

### Let

(1, 0, 0, 0), (0, 1, 0, 0), (0, 0, 1, 0), (0, 0, 0, 1)
   be the standard basis for Qᵢ and let
(1, 0, 0, 0, 0, 0, 0, 0), (0, 1, 0, 0, 0, 0, 0, 0), . . . , (0, 0, 0, 0, 0, 0, 0, 1)
   be the standard basis for

$${C}_{1} = {𝔽}_{2}^{8} .$$

### Then,

$$\begin{matrix}{f}_{1}^{( i )} = ( ( 1 , 0 , 0 , 0 ) ) = ( 1 , 0 , 0 , 0 , 0 , 0 , 0 , 0 ) , \\ {f}_{1}^{( i )} = ( ( 0 , 1 , 0 , 0 ) ) = ( 0 , 0 , 0 , 1 , 0 , 0 , 0 , 0 ) , \\ {f}_{1}^{( i )} = ( ( 0 , 0 , 1 , 0 ) ) = ( 0 , 0 , 0 , 0 , 1 , 0 , 0 , 0 ) , and \\ {f}_{1}^{( i )} = ( ( 0 , 0 , 0 , 1 ) ) = ( 0 , 0 , 0 , 0 , 0 , 0 , 0 , 1 ) .\end{matrix}$$

As a matrix with rows and columns ordered by the natural ordering of the standard basis of C₁ and Qᵢ, respectively,

$${f}_{1}^{( i )} = ( \begin{matrix}1 & . & . & . \\ . & . & . & . \\ . & . & . & . \\ . & 1 & . & . \\ . & . & 1 & . \\ . & . & . & . \\ . & . & . & . \\ . & . & . & 1\end{matrix} ) .$$

In order to specify Xᵢ, a set of tuples {(S,j,k)} is constructed where S ranges through all X-stabilizer generators with overlapping support on indices j, k∈supp(S)∩supp(Zᵢ) with j #k. It is not necessary to include all possible pairs (j,k) but every j∈supp(S)∩supp(Zᵢ) must be in at least one tuple corresponding to S. Define Xᵢ to be the vector space

$${𝔽}_{2}^{\vert \{ ( S , j , k ) \} \vert} ,$$

where the c-th standard basis element may be associated with the c-th element of {(S,j,k)}. Then, there is a map from Xᵢ to the space of X syndromes,

$${f}_{0}^{( i )} : {X}_{i} \to {C}_{0} ,$$

which, in matrix form, has a one in row r and column c if the X stabilizer associated with the c-th basis element is the r-th X stabilizer represented in H_{X}. In general, the support of the r-th row of H_{X} does not need to overlap the support of Zᵢ, in which case the r-th row of

$${f}_{0}^{( i )}$$

will be all zeroes. Example 2 below presents a simple example to illustrate this mapping more concretely.

### Example 2

Continuing with Example 1 above, assume that Zᵢ=(1, 0, 0, 1, 1, 0, 0, 1) is a stabilizer generator the weight of which is to be reduced and X₁=(1, 0, 1, 0, 1, 0, 1, 0) and X₂=(1, 1, 0, 1, 1, 0, 1, 1) are two X-stabilizer generators. The overlaps are supp(X₁)∩supp(Zᵢ)={1, 5} and supp(X₂)∩supp(Zᵢ)={1, 4, 5, 8}. For the first stabilizer, there is the tuple (X₁, 1, 5). For the second stabilizer, there are six possible tuples. One option would be to choose the tuples:

$$( {X}_{2} , 1 , 4 ) , ( {X}_{2} , 1 , 5 ) , ( {X}_{2} , 1 , 8 ) \qquad ( 20 )$$

another option would be to choose the remaining tuples:

$$( {X}_{2} , 1 , 4 ) , ( {X}_{2} , 4 , 5 ) , ( {X}_{2} , 5 , 8 ) , ( {X}_{2} , 4 , 8 ) \qquad ( 21 )$$

and yet another option would be to use all six combinations. All of these choices satisfy the property that every j∈supp(S)∩supp(Zᵢ) is in at least one tuple corresponding to S.

Consider Equation (20). In this example, only two X stabilizers are considered, therefore

$${C}_{0} = {𝔽}_{2}^{2} .$$

Let the standard basis elements (1,0) and (0,1) correspond to X₁ and X₂, respectively, and let the standard basis elements (1, 0, 0, 0), . . . ,(0, 0, 0, 1) of

$${X}_{i} = {𝔽}_{2}^{4}$$

correspond to the elements {(X₁, 1, 5), (X₂, 1, 4), (X₂, 1, 5), (X₂, 1, 8)}, in that order. Then,

$${f}_{0}^{( i )} = ( \begin{matrix}1 & 0 & 0 & 0 \\ 0 & 1 & 1 & 1\end{matrix} ) \qquad ( 22 )$$

For Equation (21), let the standard basis element (1, 0, 0, 0, 0), . . . ,(0, 0, 0, 0, 1) of

$${𝒳}_{i} = {𝔽}_{2}^{5}$$

correspond to the elements {(X₁, 1, 5), (X₂, 1,4), (X₂, 1, 5), (X₂, 1, 8)}, in that order. Then,

$${f}_{0}^{( i )} = ( \begin{matrix}1 & 0 & 0 & 0 & 0 \\ 0 & 1 & 1 & 1 & 1\end{matrix} ) \qquad ( 23 )$$

Taking all six possible tuples,

$${f}_{0}^{( i )} = ( \begin{matrix}1 & 0 & 0 & 0 & 0 & 0 & 0 \\ 0 & 1 & 1 & 1 & 1 & 1 & 1\end{matrix} ) \qquad ( 24 )$$

In Equation (18), the lxii columns of

$${f}_{0}^{( i )}$$

correspond to new qubits and the rows affect the weight of the final stabilizers. Since the goal is to reduce overhead in weight reduction, the smallest cardinality possible should be chosen. For this example, {(X₁, 1, 5), (X₂, 1, 4), (X₂, 5, 8)}reduces both the number of columns of

$${f}_{0}^{( i )}$$

and the weight of the second row. If coning, gauging, and thickening and choosing heights are performed prior to this step, then the only Z stabilizers that need to be reduced will have overlaps of size either zero or two as explained in more detail below. Then, the row weights of

$${f}_{0}^{( i )}$$

are at most one.

There is also a natural connection between Qᵢ and Xᵢ: the elements of Qᵢ are associated with qubits and Xᵢ with pairs of qubits. Make a graph with a vertex for every basis element of Qᵢ and with an edge connecting the pair of qubits in (S,j,k)∈Xᵢ. The map

$${\partial }_{1}^{( i )} :$$

Qᵢ→Xᵢ is called the coboundary map of the graph and takes the vertices to the basis elements of Xᵢ that include those vertices. For example, the coboundary map of the square with vertices V={v₁,v₂,v₃,v₄} and edges E={v₁v₂, v₂v₃, v₃v₄, v₄v₁} is the |E|×|V| edge-vertex incidence matrix

$${v}_{1} {v}_{2} {v}_{3} {v}_{4}$$

$$\begin{matrix}{v}_{1} {v}_{2} \\ {v}_{2} {v}_{3} \\ {v}_{3} {v}_{4} \\ {v}_{4} {v}_{1}\end{matrix} ( \begin{matrix}1 & 1 & 0 & 0 \\ 0 & 1 & 1 & 0 \\ 0 & 0 & 1 & 1 \\ 1 & 0 & 0 & 1\end{matrix} )$$

### Example 3

Continuing Example 2, suppose that Zᵢ=(1,0,0,1,1,0,0,1) is a stabilizer generator the weight of which we want to reduce and X₁=(1,0,1,0,1,0,1,0) and X₂=(1,1,0,1,1,0,1,1) are two X-stabilizer generators. Then,

$${Q}_{i} = {𝔽}_{2}^{4}$$

and Xᵢ={(X₁, 1, 5), (X₂, 1, 4), (X₂, 5, 8)} may be chosen. Order the rows of

$${\partial }_{1}^{( i )}$$

by the elements of Xᵢ and the columns by the natural ordering of the standard basis on Qᵢ. Since 1 and 5 are the first and third elements of the support of Zᵢ, place a one in the first and third columns of the first row. Extending this to obtain

$${\partial }_{1}^{( i )} = ( \begin{matrix}1 & 0 & 1 & 0 \\ 1 & 1 & 0 & 0 \\ 0 & 0 & 1 & 1\end{matrix} ) .$$

Using Xᵢ={(X₁, 1, 5), (X₂, 1, 4), (X₂, 4, 5), (X₂, 5, 8), (X₂, 4, 8)} instead gives:

$${\partial }_{1}^{( i )} = ( \begin{matrix}1 & 0 & 1 & 0 \\ 1 & 1 & 0 & 0 \\ 0 & 1 & 1 & 0 \\ 0 & 0 & 1 & 1 \\ 0 & 1 & 0 & 1\end{matrix} ) .$$

Referring back to Equation (18), the number of rows of

$${\partial }_{1}^{( i )}$$

determines the number of new qubits in the weight reduction added at this stage of the weight-reduction process. The row and column weights also affect the parameters of the final stabilizers. The first choice of Xᵢ does not use any qubit index more than once for a given stabilizer, reducing the column weight of

$${\partial }_{1}^{( i )} .$$

The rows will always have weight of two by definition.

As alluded to in Example 2, assuming that coning is applied to the output of all the previous steps, the input will satisfy w_{X}≤5 and q_{X}≤3 as a consequence of Lemmas 1, 2, and 3 and are of the form given in Equation (12). The Z stabilizers corresponding to the bottom row of Equation (12),

$$( \begin{matrix}{H}_{Z} ⊗ {I}_{ℓ} & 0 \\ {I}_{n} ⊗ {H}_{ℓ} & {H}_{X}^{T} ⊗ {I}_{ℓ − 1}\end{matrix} ) ,$$

have weight no more than five since H_{X} there has q_{X}≤3, and therefore do not need to be reduced. The Iₙ_{_{X}}⊗H^{T} term in the X stabilizers contributes two to the weight but overlaps the 0 block in the Z stabilizers that need reduction. Thus, the support of an X stabilizer can therefore only intersect the support of Zᵢ zero or two times, adding at most one (possible) element to X. This keeps the space smaller compared to applying coning to a generic input.

Then, the space [symbol] is constructed. Recall from above that the chain

$${𝒜}_{i} : {𝒬}_{i} {\to }^{{\partial }_{1}^{( i )}} {𝒳}_{i} {\to }^{{\partial }_{0}^{( i )}} {ℛ}_{i}$$

is related to the new auxiliary spaces and the chain [symbol] :C₂→C₁→C₀ to the original code. The logical operators are determined by the chain complex of homologies, the exact sequence of which is given in Equation A12.

$$0 \to {H}_{1} ( {𝒜}_{i} ) \to {H}_{1} ( ℬ ) \to {H}_{1} ( cone ( {f}^{( i )} ) ) \to {H}_{0} ( {𝒜}_{i} ) ) \qquad ( 25 )$$

The term H₁( [symbol] ) represents the logical operators of the original code plus the logical operator created by deleting the Z stabilizer that is being reduced. The logical operators of the output of coning are elements of H₁ (cone(f⁽ⁱ⁾)). In order to find a relationship between the two, recall that weight reduction is considered an operation on a code as compared to a method of constructing a new code. Hence, k is required to remain the same throughout the entire process. To achieve this, H₀( [symbol] ᵢ) needs to be zero by exactness, and the space [symbol] ᵢ is designed accordingly. Recall that

$${H}_{0} ( {𝒜}_{i} ) = ker {\partial }_{0}^{( i )} / im {\partial }_{1}^{( i )} .$$

It follows that [symbol] ᵢ and

$${\partial }_{0}^{( i )}$$

should be chosen such that

$${\partial }_{0}^{( i )} = im {\partial }_{1}^{( i )} .$$

Define [symbol] ᵢ to be the [symbol] ₂-vector space with a basis element for every element of the chosen cycle basis (as illustrated in more detail in Example 4 below) of the graph defined by Qᵢ and Xᵢ, and

$${\partial }_{0}^{( i )}$$

:X₁→ [symbol] ᵢ by the coboundary map sending the edges to the cycles in which they are contained. In cases where the graph has no cycles, it may not be necessary to construct Rᵢ as no extra logical qubit is introduced.

The following example shows that not all cycle bases are equivalent for weight reduction purposes. In “Building manifolds from quantum codes”, Geom. Funct. Anal. 31, 855 (2021), the disclosure of which is incorporated herein in its entirety, Freedman and Hastings provide an algorithm called the decongestion lemma to find a cycle basis such that each edge appears in at most O(log|Qᵢ|²) cycles and the cycle length of which is O(|Qᵢ|log|Qᵢ|). This may not be the minimum-weight cycle basis but these conditions are designed to control the column and row weights of

$${\partial }_{0}^{( i )} .$$

Alternative algorithms, such as Horton's algorithm for finding a minimum-weight cycle basis as described in “A polynomial-time algorithm to find the shortest cycle basis of a graph”, SIAM J. Comput. 16, 358 (1987), the disclosure of which is incorporated herein in its entirety, may be used.

### Example 4

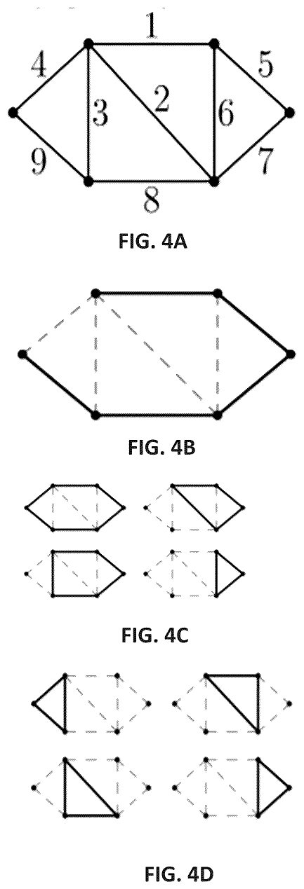

At a high level, a cycle basis may be conceptualized as a set of cycles of a graph such that every cycle in the graph can be expressed as a combination of cycles in the basis. To determine a cycle basis of an input graph, an example of which is shown in FIG. 4A, one may begin with its spanning tree. One possible choice of the spanning tree of the input graph in FIG. 4A is shown in FIG. 4B. The fundamental cycle basis associated with this tree is given by adding the edges from FIG. 4A that are not found in FIG. 4B. Thus, the addition of the edges 4, 2, 3, and 6 from FIG. 4A produces the fundamental cycle basis shown in FIG. 4C. Interpreted in the context of Qᵢ and Xᵢ, there is provided:

$${\partial }_{0}^{( i )} = ( \begin{matrix}1 & 0 & 0 & 1 & 1 & 0 & 1 & 1 & 1 \\ 1 & 1 & 0 & 0 & 1 & 0 & 1 & 0 & 0 \\ 1 & 0 & 1 & 0 & 1 & 0 & 1 & 1 & 0 \\ 0 & 0 & 0 & 0 & 1 & 1 & 1 & 0 & 0\end{matrix} ) ,$$

where the rows correspond to the cycles read left to right and then top to bottom in FIG. 4C and the columns correspond to the edges in FIG. 4A in numerical order. The two columns fully populated with ones correspond to the edges 5 and 7, which appear in every cycle of FIG. 4C. As may be discerned from FIGS. 4A to 4D, this results in a potentially undesirable increase in the column weight q_{X} according to Equation (18).

Alternatively, FIG. 4D shows a minimum-weight cycle basis for the input graph of FIG. 4A. In the minimum-weight cycle basis, the total sum of the number of edges in each basis element is minimal with

$${\partial }_{0}^{( i )} = ( \begin{matrix}0 & 0 & 1 & 1 & 0 & 0 & 0 & 0 & 1 \\ 1 & 1 & 0 & 0 & 0 & 1 & 0 & 0 & 0 \\ 0 & 1 & 1 & 0 & 0 & 0 & 0 & 1 & 0 \\ 0 & 0 & 0 & 0 & 1 & 1 & 1 & 0 & 0\end{matrix} ) ,$$

where the rows correspond to the cycles read left to right and then top to bottom in FIG. 4D and the columns correspond to the edges in FIG. 4A in numerical order. The minimum-weight basis may avoid increasing q_{X} but is not guaranteed to do so in every case. The known decongestion lemma, not demonstrated in this example, results in low row and column weights but only with high probability. Note that the randomness in the decongestion lemma may produce variations in the parameters of the final code.

Having chosen a cycle basis, some basis elements may contain a large number of edges. Large cycles lead to high-weight rows of

$${\partial }_{0}^{( i )}$$

and in turn high-weight X stabilizers. For a LDPC input code, this would produce a non-LDPC output and undermine the reduction of w_{X} in gauging. To address this, auxiliary edges may be added to divide the cycles into smaller cycles, in a process called cellulation. The map and the resulting stabilizers are highly dependent on the choice of cellulation. In this sense, some cellulations approaches may be better suited than others. For the purposes of illustration, the present disclosure adopts the cellulation method of any time a cycle has length greater than four, auxiliary edges are added to reduce the length down to four with no new vertices (qubits) introduced. The newly added auxiliary edges must be added to Xᵢ but without an associated X stabilizer, e.g. (_,j,k). Cellulation may affect the maps

$${\partial }^{( i )} ,$$

but not

$${f}_{0}^{( i )} .$$

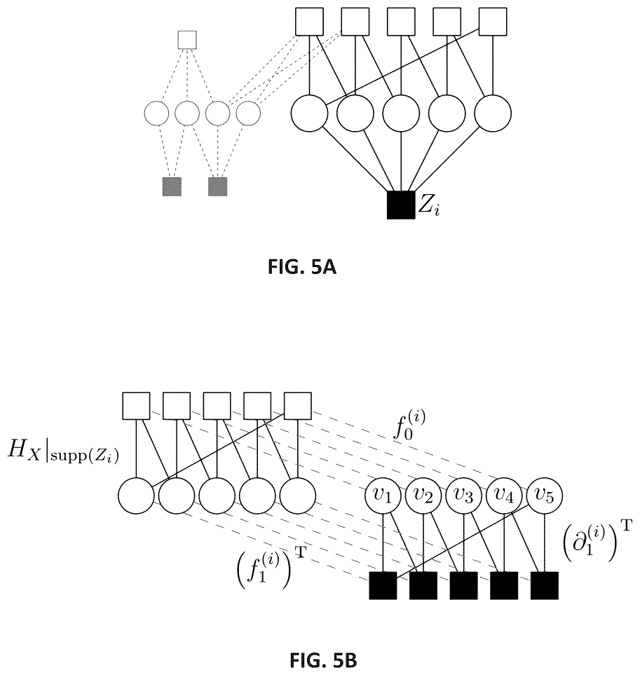

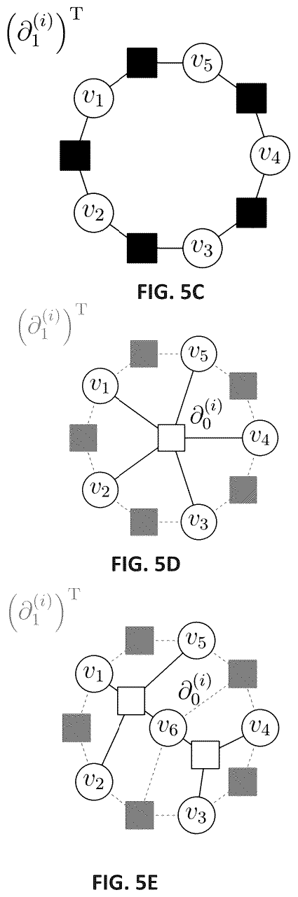

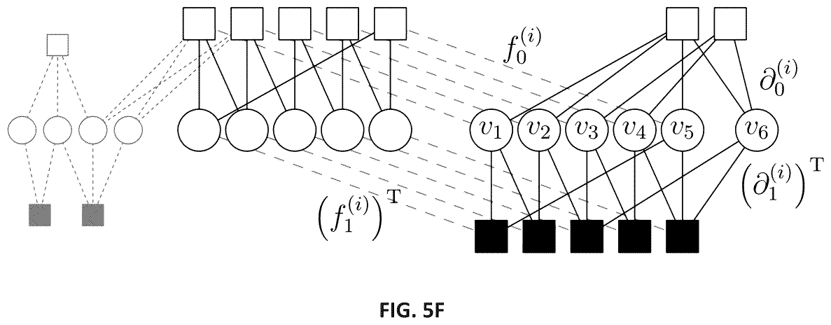

The additions to ∂⁽ⁱ⁾ appear in the stabilizers given in Equation (18) and could affect the LDPC properties of the output. An explicit example is shown in Example 5 and another graphical demonstration is provided in FIGS. 5A-F.

FIG. 5A shows an exemplary Tanner graph for which the weight of the stabilizer Zᵢ is to be reduced via coning. FIG. 5B show the newly introduced qubits v₁-v₅. The number of the new qubits is always equal to the number of X stabilizers that share some suppose with Zᵢ, and the number of Z stabilizers replacing Zᵢ is always exactly the number of qubits in the support of Zᵢ. The maps

$${f}_{1}^{( i )} and {f}_{0}^{( i )}$$

always have this form and

$${\partial }_{1}^{( i )}$$

is always the same structure as H_{X}|_{supp(Z}_{ᵢ}₎, e.g.

$${( {\partial }_{1}^{( i )} )}^{T}$$

is similar to H_{X}|_{supp(Z}_{ᵢ}₎ with variables and checks swapped. This creates a new X-logical operator on the qubits v₁,v₂,v₃,v₄,v₅, hence the need for an updated

$${\partial }_{0}^{( i )} .$$

It is noted that the shaded and/or dashed portions of the Tanner graph in FIG. 5A remain unchanged, and, for clarity, they are omitted in FIG. 5B.

The

$${\partial }_{1}^{( i )}$$

is redrawn on its own in FIG. 5C showing the cycle that leads to the new logical operator. In FIG. 5D, the logical operator is added to the X stabilizers, creating the structure of

$${\partial }_{0}^{( i )} .$$

FIG. 5E shows that the weight of the new X stabilizer is 5, which according to the previously established threshold of 4, is sufficiently high to trigger cellulation that causes an additional qubit v₆ to be added. In FIG. 5F, the new Tanner graph after coning is reconstructed.

### Example 5

Consider coning the following inputs:

$${H}_{X} = ( \begin{matrix}1 & 1 & . & . & . & . & . & . & . & . \\ . & 1 & 1 & . & . & . & . & . & . & . \\ . & . & 1 & 1 & . & . & . & . & . & . \\ . & . & . & 1 & 1 & . & . & . & . & . \\ . & . & . & . & 1 & 1 & . & . & . & . \\ . & . & . & . & . & 1 & 1 & . & . & . \\ 1 & . & . & . & . & . & 1 & . & . & . \\ . & . & . & 1 & . & . & . & 1 & . & . \\ . & . & . & . & . & . & . & 1 & 1 & . \\ . & . & . & . & . & . & . & . & 1 & 1 \\ . & . & . & . & . & . & . & 1 & . & 1\end{matrix} ) ,$$

$${H}_{Z} = ( \begin{matrix}1 & 1 & 1 & 1 & 1 & 1 & 1 & 1 & 1 & 1\end{matrix} ) .$$

There is only one Z stabilizer to be reduced with support on all the qubits, so

$${Q}_{1} = {𝔽}_{2}^{10} .$$

Since Z₁ has full support,

$${f}_{1}^{( 1 )}$$

is the identity map. The overlaps of H_{X} and H_{Z} provide

$${𝒳}_{1} = {𝔽}_{2}^{11}$$

with standard basis elements in correspondence with the edges

$$\{ \begin{matrix}( {X}_{1} , 1 , 2 ) , ( {X}_{2} , 2 , 3 ) , ( {X}_{3} , 3 , 4 ) , ( {X}_{4} , 4 , 5 ) , ( {X}_{5} , 5 , 6 ) , ( {X}_{6} , 6 , 7 ) , ( {X}_{7} , 7 , 1 ) , ( {X}_{8} , 4 , 8 ) , \\ ( {X}_{9} , 8 , 9 ) , ( {X}_{10} , 9 , 10 ) , ( {X}_{11} , 10 , 8 )\end{matrix} \} \qquad ( 25 )$$

Since the j-th element of Xᵢ is associated with the j-th X stabilizer,

$${f}_{0}^{( i )}$$

is also the identity.

The graphical relationship between Qᵢ and Xᵢ may be visualized by restricting H_{X} to the qubits on the support of the Z stabilizer that are being reduced, which in this case is every qubit, as the edge-vertex incidence matrix:

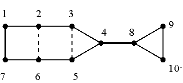

The cycles are [symbol] {(1, 2, 3, 4, 5, 6, 7),(8, 9, 10)}, giving

$${\partial }_{0}^{( 1 )} = ( \begin{matrix}1 & 1 & 1 & 1 & 1 & 1 & 1 & 0 & 0 & 0 & 0 \\ 0 & 0 & 0 & 0 & 0 & 0 & 0 & 0 & 1 & 1 & 1\end{matrix} ) ,$$

where the edges (columns) are ordered as in Equation (25). Note that the edge 4-8 does not participate in any cycles and corresponds to the empty column. This will produce a high-weight X stabilizer in Equation (18) and requires cellulation by adding the dashed edges 2-6 and 3-5 and (_,2,6), (_,3,5) to X₁. Leading to the cycles being:

$${ℛ}_{i} = \{ ( 1 , 2 , 6 , 7 ) , ( 2 , 3 , 5 , 6 ) , ( 3 , 4 , 5 ) , ( 8 , 9 , 10 ) \}$$

$$and$$

$${\partial }_{0}^{( 1 )} = ( \begin{matrix}1 & 0 & 0 & 0 & 0 & 1 & 1 & 0 & 0 & 0 & 0 & 1 & 0 \\ 0 & 1 & 0 & 0 & 1 & 0 & 0 & 0 & 0 & 0 & 0 & 1 & 1 \\ 0 & 0 & 1 & 1 & 0 & 0 & 0 & 0 & 0 & 0 & 0 & 0 & 1 \\ 0 & 0 & 0 & 0 & 0 & 0 & 0 & 0 & 1 & 1 & 1 & 0 & 0\end{matrix} ) ,$$

where the columns to the right of the vertical line correspond to the new edges added by the cellulation. The new edges are not associated with any stabilizers, so

$${f}_{0}^{( 1 )}$$

simply adjoins zero rows. With the new X₁,

$${\partial }_{1}^{( 1 )} = ( \frac{\begin{matrix}1 & 1 & . & . & . & . & . & . & . & . \\ . & 1 & 1 & . & . & . & . & . & . & . \\ . & . & 1 & 1 & . & . & . & . & . & . \\ . & . & . & 1 & 1 & . & . & . & . & . \\ . & . & . & . & 1 & 1 & . & . & . & . \\ . & . & . & . & . & 1 & 1 & . & . & . \\ 1 & . & . & . & . & . & 1 & . & . & . \\ . & . & . & 1 & . & . & . & 1 & . & . \\ . & . & . & . & . & . & . & 1 & 1 & . \\ . & . & . & . & . & . & . & . & 1 & 1 \\ . & . & . & . & . & . & . & 1 & . & 1\end{matrix}}{\begin{matrix}. & 1 & . & . & . & 1 & . & . & . & . \\ . & . & 1 & . & 1 & . & . & . & . & .\end{matrix}} ) ,$$

where the rows below the horizontal line correspond to the cellulation.

### Example 6

The cellulation threshold of four is used in this example, but alternative schemes may be applied. Consider cellulating the octagon of solid edges 1 to 8 the Equation (26) graphically illustrated below by triangulation via the dashed edges 9 to 13:

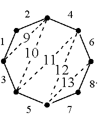

This transforms the cycle (1 1 1 1 1 1 1 1) to

$$( \begin{matrix}1 & 1 & . & . & . & . & . & . & 1 & . & . & . & . \\ . & . & 1 & . & . & . & . & . & 1 & 1 & . & . & . \\ . & . & . & 1 & . & . & . & . & . & 1 & 1 & . & . \\ . & . & . & . & 1 & . & . & . & . & . & 1 & 1 & . \\ . & . & . & . & . & 1 & . & . & . & . & . & 1 & 1 \\ . & . & . & . & . & . & 1 & 1 & . & . & . & . & 1\end{matrix} ) ,$$

where the columns represent the edges of Equation (26) in numerical order. This is the gauging equation, given in Equation (10). Cellulating may be conceptualized as performing the role of gauging for cycles by gauging a single row of

$${\partial }_{0}^{( i )} .$$

If every cycle in the cycle basis is cellulated, then every row of

$${\partial }_{0}^{( i )}$$

is “gauged” for a fixed i. However, this will not necessarily be equivalent to applying gauging directly, because the edge labels must be consistent between all of the cycles and therefore the columns cannot always be simultaneously permuted into the form of Equation (10) for every cycle.

Then, in some embodiments, if q_{X} is higher than desired or d_{Z} is lower than desired, an extra round of thickening and choosing heights may be performed with the roles of X and Z interchanged:

$$𝒜 : {𝔽}_{2}^{{n}_{Z}} {←}^{{H}_{Z}} {𝔽}_{2}^{n} {←}^{{H}_{X}^{T}} {𝔽}_{2}^{{n}_{X}} ,$$

$$ℬ : {𝔽}_{2}^{ℓ - 1} {←}^{{H}_{ℓ}} {𝔽}_{2}^{ℓ} .$$

The cellulation and the optional second thickening and height choosing may also be referred to as the reduced cone.

With the full coning procedure described, reference is made back to the logical operators introduced in Equation (25). For simplify and clarity, it is assumed that Z stabilizers are reduced one at a time using Equation (15) instead of Equation (17). If an extra round of thickening and choosing heights is used, the logical operators described here will be modified as discussed in the “Effects on Iterative Decoding” section below.

By definition,

$${H}_{1} ( {𝒜}_{i} ) = k e r ( {\partial }_{1}^{( i )} ) .$$

The space Qᵢ contains the full support of Zᵢ. Each element of Xᵢ is associated with two elements of Qᵢ by construction, so rows of

$${\partial }_{1}^{( i )}$$

will always have weight two. Thus, the all-ones vector will always be an element of

$$k e r ( {\partial }_{1}^{( i )} ) ,$$

or in other words, Zᵢ is said to commute with all the X stabilizers with which it overlaps. Anything else in the kernel commutes with all the X stabilizers in the overlap of Zᵢ and is therefore a Z stabilizer or a Z logical operator contained entirely in the support of Zᵢ. A stabilizer does not change the quotient of the previous logical operators and the stabilizer, but a Z logical operator is more problematic. Codes with such Z logical operators are called unreasonable in the Hastings papers and codes that are not unreasonable are called reasonable. Note that the present disclosure is limited to reasonable codes and the modifications to coning required for unreasonable codes are described in the Hastings papers which have been incorporated herein in their entireties. Given a reasonable code, applying the exactness condition throughout Equation (25), the isomorphism theorem (for groups) provides

$${H}_{1} ( c o n e ( {f}^{( i )} ) ) ≅ {H}_{1} ( ℬ ) / ker {\partial }_{1}^{( i )} .$$

The quotient removes the extra logical operator caused by removing Zᵢ for reduction, showing \tilde{k}=k.

It may be discerned from the matrices that the parameters after coning may be more complex compared to the previous steps. With \tilde{k}=k, the pre-cellulation w_{Z}≤5 can be increased through cellulation. In other words, the more a vertex is reused for adding new edges to create the cellulation, the more w_{Z} can increase. If a vertex is used x times in cellulation, there will be a Z-stabilizer generator of at least weight x+2, up to potentially x+4. Coning does not modify q_{Z}, and its effect on q_{X} depends on how many edges are reused in cycles which could be a large number. In cases where the number of recused edges is high, a second round of thickening and choosing heights could be implemented by swapping the roles of X and Z. If this is done, w_{Z} will increase by two, q_{Z} will still remain the same, and \tilde{w}_{X} will be the larger value of 1) w_{X} before the second round of thickening, and 2) 2+q_{Z}. The following Lemma 4 summarizes these results for convenience. The proofs for one or more points of Lemma 4 follow from the discussions above except for (d) and (g), which are derived from the Hastings papers. The length n follows from (a) to (c). Applying Lemma 3 to the output provides the resulting parameters after a second round of thickening and choosing heights.

### Lemma 4

Let variables without a tilde refer to the input to coning and let variables with a tilde refer to its output. Assume that the input has had copying, gauging, and thickening and choosing heights applied, where h is the maximum number of times any particular height is used. Assume that the output is subject to cellulation such that within each cycle, any given qubit is used at most once in the cellulation. Before applying a possible second round of thickening and choosing heights, Lemma 4 is as follows:

$${\tilde{n}}_{X} increases by the number of cycles \qquad ( a )$$

$${\tilde{n}}_{Z} increases by w - 1 for every weigth w stabilizer that is reduced via coning \qquad ( b )$$

$$\tilde{k} = k \qquad ( c )$$

$${\tilde{w}}_{X} \leq 5 + h \qquad ( d )$$

$${\tilde{w}}_{X} \leq 7 \qquad ( e )$$

$${\tilde{q}}_{Z} = {q}_{Z} \qquad ( f )$$

$${d}_{X} \geq {d}_{X} \qquad ( g )$$

Proof for one or more the above that are not readily derived from the Hastings papers are provided as follows:
(a) Having undergone copying, gauging, and thickening and choosing heights, w_{X}≤5 before coning. Cellulation ensures that new X stabilizers

$${\partial }_{0}^{( i )}$$

have a maximum weight of four. Thus, only the increase in weight of the old X stabilizers under coning, i.e., the bottom row of \tilde{H}_{X} in Equation (18):

$$( {f}_{0}^{( 1 )} … {f}_{0}^{( m )} {H}_{X} )$$

needs to be determined. Having undergone copying, gauging, and thickening and choosing heights, the X stabilizers that overlap with the Z stabilizers are reduced either zero or two times as per Equation (12), contributing either nothing or one element to Xᵢ, respectively. So

$${f}_{0}^{( i )}$$

has a maximum row weight of one by construction.

Recall that the weight of Z stabilizers from the rows (H_{Z}⊗ [symbol] ) in Equation (12) is reduced, where only one row is kept per [symbol] rows. The supports of two Z stabilizers are disjoint if they are associated with different heights. This row overlaps the supports of the X stabilizers in the H_{Z}⊗ [symbol] block of the thickening stabilizers, which has w_{X}≤3 due to gauging. If an X stabilizer overlaps with one of the Z stabilizers that is reduced, then at least two qubits of its support are within the set of qubits associated with the height of that Z stabilizer. This results in a maximum of one qubit that could be in any other height. By commutativity, it therefore cannot overlap with any Z stabilizer from another height. Thus, an X stabilizer can only get added weight from

$${f}_{0}^{( i )}$$

within exactly one height.

Note that \tilde{q}_{X} can be high (e.g. such as 8 or above) and require thickening with choosing heights, and \tilde{d}_{Z} can be low (e.g. less than the distance threshold) and require thickening.

Quantum weight reduction is highly asymmetric between the X and Z stabilizers. Swapping the roles of X and Z can produce different results for asymmetric codes. For example, weight reducing the QRM(4) stabilizers in Equation (14) using [symbol] =3 produces a [symbol] 724,1,d_{X}/d_{Z}=16/3 [symbol] code with (\tilde{w}_{X}, \tilde{q}_{X},\tilde{q}_{Z},\tilde{q}_{Z})=(8, 3, 6, 5). By swapping the stabilizers, weight is reduced while keeping as many algorithmic parameters fixed as possible, and then swapping back the stabilizers produces a [symbol] 1392, 1, 7/9 [symbol] code with (\tilde{w}_{X},\tilde{q}_{X},\tilde{w}_{Z},\tilde{q}_{Z})=(9, 3, 6, 6). The increase in qubits here stems from having more stabilizers to reduce during copying and q_{X} is larger during gauging. These extra qubits are then multiplied due to using the same amount of thickening.

Overhead Reduction with Modified Copying

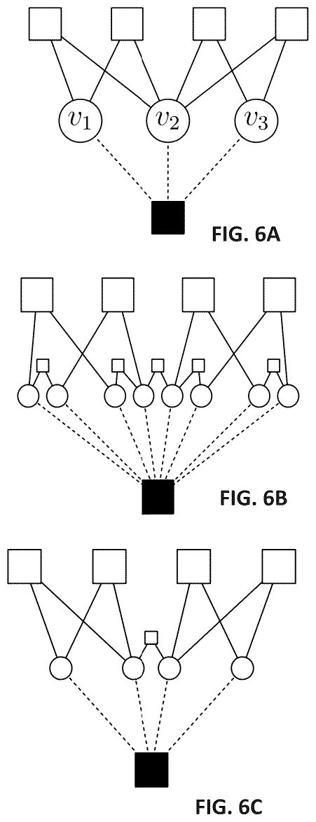

With the above steps using [symbol] =3 and heights=(2, 1, 2, 1, 2, 3, 1, 3, 3, 1), the Reed-Muller QRM(4) stabilizers given in Equation (14) produce a [symbol] 724, 1, 3 [symbol] code. This is a significant increase in resources to protect a single logical qubit. The copying step described above may be modified to reduce the overhead. Referring back to the Tanner graph shown in FIG. 1A which is reproduced in FIG. 6A, it may be discerned from FIG. 1B that any column the weight of which is not equal to q_{X} contains unused qubits. Thus, in some embodiments, during the copying step, a qubit is only copied as many times as its column weight, as better shown in FIG. 6B described in more detail below. Byway of an example, applying the modified copying step (also referred to as the reduced copying) to the Reed-Muller QRM(4) code produces a [symbol] 512, 1, 2 [symbol] code. The reduction of resources propagated through the full procedure may be more pronounced when q_{X} is much larger (e.g. twice as much) than the median column weight.

Note that copying results in q_{X}=3 but some of the new qubits are only in the support of two X stabilizers for both the original and the modified copying procedures. Thus, in some embodiments, with a targeted copying method, all new qubits can be made to to support exactly targ_{q}_{_{X}} number of X stabilizers for some target column weight of targ_{q}_{_{X}}≥3. Referring to FIG. 1B, it can be observed that v_{i,1} and v_{i,q}_{_{X}} can accept targ_{q}_{_{X}}−1 number of edges instead of targ_{q}_{_{X}}−2, thus reducing the number of qubits needed for copying. By way of an example, applying this to FIG. 1B with targ_{q}_{_{X}}=3 produces FIG. 6C. As a further example, applying this to the Reed-Muller code with targ_{q}_{_{X}}=3 produces a [symbol] 315, 1,2 [symbol] code.

In a further still example, to ensure that some of the overhead reduction of the three previously mentioned codes do not merely stem from decreased code distance, algorithmic parameters that produce codes with equal distance and similar values of (\tilde{w}_{X}, \tilde{q}_{X}, \tilde{w}_{Z}, \tilde{q}_{Z}) have been examined. The distance constraint may necessitate a second round of thickening ( [symbol] ₂) after coning. With the original copying, a [symbol] 1508, 1,4 [symbol] code with (\tilde{w}_{X}, \tilde{q}_{X}, \tilde{w}_{Z}, \tilde{q}_{Z})=(9, 5, 6, 6) using [symbol] = [symbol] ₂=2. The reduced and targeted copying described herein generated a [symbol] 1334, 1,4 [symbol] and a [symbol] 832, 1,4 [symbol] code, respectively, both with (\tilde{w}_{X}, \tilde{q}_{X}, \tilde{w}_{Z}, \tilde{q}_{Z})=(8, 5, 6, 5) and using [symbol] =3 and [symbol] ₂=2.

The improved copying methods (e.g. reduced copying and targeted copying) do not decrease the distance of the input code. The drop in distance from the original [symbol] 15, 1, 3 [symbol] code in the previous examples is instead due to a lesser increase in d_{Z} during copying. The codes after copying, reduced copying, and targeted copying have parameters [symbol] 60, 1, 7 [symbol] , [symbol] 32, 1, 4 [symbol] , and [symbol] 16, 1, 3 [symbol] , respectively. Thus, by holding the output distance constant, an improvement in resource use from the two improved copying techniques may be obtained. The precise functionalities resulting from the reduced and targeted copying methods are summarized as follows.

### Lemma 5

Let variables without a tilde refer to the input to copying, let variables with a tilde refer to its output, and let

$${q}_{X}^{( i )}$$

refer to the number of X-stabilizer generators that participate nontrivially on qubit i. Then, reduced copying may result in

$$\tilde{n} = {\sum }_{i = 1}^{n} {q}_{X}^{( i )} \leq n {q}_{X} \qquad ( a )$$

$${\tilde{n}}_{X} = {n}_{X} + {\sum }_{i = 1}^{n} ( {q}_{X}^{( i )} - 1 ) \leq {n}_{X} + ( {q}_{X} - 1 ) n \qquad ( b )$$

$${\tilde{n}}_{Z} = {n}_{Z} \qquad ( c )$$

$$\tilde{k} = k \qquad ( d )$$

$${\tilde{w}}_{{X}^{=}} {w}_{X} \qquad ( e )$$

$${\tilde{q}}_{X} = min \{ {q}_{X} , 3 \} \qquad ( f )$$

$${\tilde{w}}_{Z} \leq {q}_{X} {w}_{Z} \qquad ( g )$$

$${\tilde{q}}_{Z} = {q}_{Z} \qquad ( h )$$

$${\tilde{d}}_{X} = {d}_{X} \qquad ( i )$$

$${\tilde{d}}_{Z} \geq {d}_{Z} {min}_{i} \{ {q}_{X}^{( i )} \} \qquad ( j )$$

The targeted copying with a target of t=targ_{q}_{_{X}}≥3 provides:

$$\begin{matrix}\tilde{n} = {\sum }_{i = 1}^{n} max ( 1 , ( {q}_{X}^{( i )} + 1 - t ) ) \\ \leq n max \{ 1 , ( {q}_{X} + 1 - t ) \}\end{matrix} \qquad ( a )$$

$$\begin{matrix}{\tilde{n}}_{X} = {n}_{X} + {\sum }_{i = 1}^{n} max \{ 0 , ( {q}_{X}^{( i )} - t ) \} \\ \leq {n}_{X} + ( {q}_{X} - t ) n\end{matrix} \qquad ( b )$$

$${\tilde{n}}_{Z} = {n}_{Z} \qquad ( c )$$

$$\tilde{k} = k \qquad ( d )$$

$${\tilde{w}}_{X} = {w}_{X} \qquad ( e )$$

$${\tilde{q}}_{X} = min \{ {q}_{X} , t \} \qquad ( f )$$

$${\tilde{w}}_{Z} \leq {w}_{Z} max \{ 1 , ( {q}_{X} + 1 - t ) \} \qquad ( g )$$

$${\tilde{q}}_{Z} = {q}_{Z} \qquad ( h )$$

$${\tilde{d}}_{X} = {d}_{X} \qquad ( i )$$

$${\tilde{d}}_{Z} \geq {d}_{Z} max \{ 1 , {min}_{i} ( {q}_{X}^{( i )} + 1 - t ) \} \qquad ( j )$$

The inequalities are saturated when

$${q}_{X}^{( i )} = {q}_{X}$$

for all i, including the special case of regular LDPC codes.

### Quantum Weight Reduction

This section provides a simpler alternative description of the previously described quantum weight reduction method using the homological algebra and coning formalisms described herein. All three copying variants, Hastings's original as shown in FIG. 1B, the reduced copying as shown in FIG. 6B, and the targeted copying as shown in FIG. 6C, may be viewed in the same framework. With the hindsight of coning, Equation (8) may be conceptualized as being in the form of a mapping cone where H is given by Equation (11) as:

$${\tilde{H}}_{X} = ( \begin{matrix}{H}_{X}^{( r )} & {f}_{1}^{T} \\ & {H}_{ℓ}\end{matrix} ) , {\tilde{H}}_{Z} = ( \begin{matrix}{H}_{Z}^{( r )} & {f}_{2}\end{matrix} ) \qquad ( 27 )$$

Proceeding one column at a time, remove the column of weight qᵢ to be reduced to obtain

$${H}_{X}^{( r )} and {H}_{Z}^{( r )} .$$

Without all columns,

$${H}_{X}^{( r )} and {H}_{Z}^{( r )}$$

may not commute and therefore cannot form the standard chain complex. Instead, the following complex is obtained:

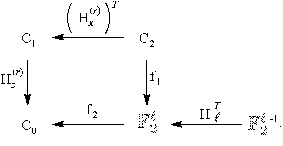

In order to be a valid chain complex,

$${f}_{2} {H}_{ℓ}^{T} = 0$$

is required, and in order to be a valid chain map,

$${f}_{2} {f}_{1} = {{H}_{Z}^{( r )} ( {H}_{X}^{( r )} )}^{T}$$

is required. The number of solutions for f₂ is the size of the left kernel of

$$( \begin{matrix}{f}_{1} & {H}_{ℓ}^{T}\end{matrix} ) .$$

Viewed as a matrix, each column of f₁ may need to have a weight of zero or one and the columns should have support exactly corresponding to the row support of the deleted column of H_{X}. Choosing [symbol] =q_{X} uniformly for all variables and limiting the row weight of f₁ to one gives Hastings' copying. Choosing [symbol] =qᵢ separately for each variable and limiting the row weight of f₁ to one result in reduced copying. Choosing [symbol] =qᵢ−2 and letting the first and last rows of f₁ have weight two with other rows having weight one result in the targeted copying with targ_{q}_{_{X}}=3.

Gauging removes rows of H_{X}, preserving the commutativity between the stabilizers, and can therefore form the standard chain complex. Removing a row of weight wᵢ from H_{X} to obtain

$${H}_{x}^{( r )} ,$$

the associated complex is:

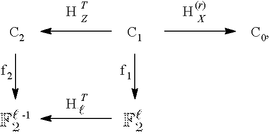

with [symbol] =wᵢ−2, the columns of f₁ corresponding to the support of the deleted X stabilizer having weight one, other columns having weight zero, first and last rows having weight two, and all other rows having weight one. The stabilizers are:

$${\tilde{H}}_{X} = ( \begin{matrix}{H}_{ℓ}^{( r )} & \\ {f}_{1} & {H}_{ℓ}^{T}\end{matrix} ) , \tilde{{H}_{Z}} = ( \begin{matrix}{H}_{Z} & {f}_{2}^{T}\end{matrix} )$$

and

$${H}_{ℓ}^{T} {f}_{2} = {f}_{1} {H}_{Z}^{T} .$$

There is a unique solution for f₂, since

$${H}_{ℓ}^{T}$$

has a left inverse.

Quantum weight reduction may therefore be conceptualized as applying two cones, a first tensor product of chain complexes, and then a second cone. This unifies the procedure into a homological algebraic framework, replacing the more difficult algebraic topological framework of the original description.

### Effects on Iterative Decoding

Despite its advantages, quantum weight reduction method described above generally alters the underlying structure of the original code. In the absence of any obvious structure in the output, the available decoders are those applicable to wide ranges of codes, such as belief propagation (BP). These iterative algorithms are highly sensitive to the topology of the Tanner graph as has been studied in known studies. The fact that stabilizers must commute forces all stabilizer codes to have 4-cycles. For CSS codes, these unavoidable cycles are between the X and Z stabilizers. If X-Z correlations are ignored and the two types of stabilizers are decoded independently, it is beneficial to reduce the number of short cycles from only H_{X} and only H_{Z}. Unfortunately, the above weight-reduction procedure introduces a significant amount of new 4-cycles.

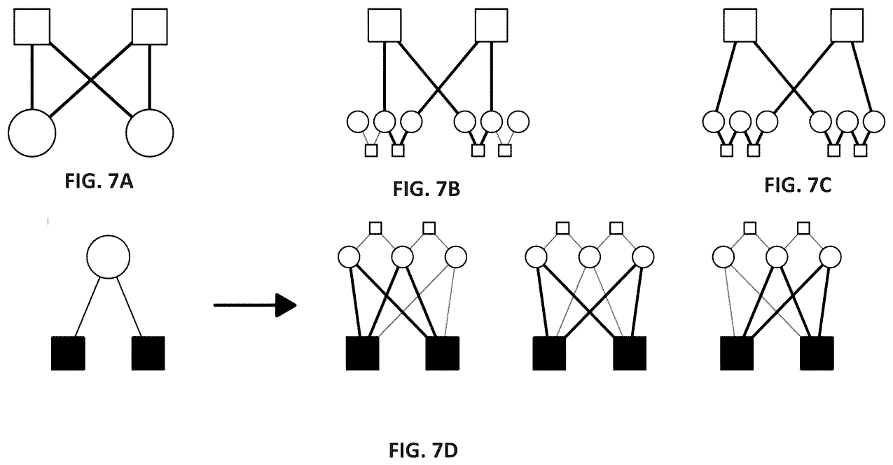

Since the Tanner graph of the repetition code (and its transpose) has no cycles, expanding the variable nodes in copying does not introduce any new cycles in the X stabilizers. However, the degree of freedom present in assigning a qubit to one of its copies in the repetition code can have important consequences as shown in FIGS. 7A-D. Consider the 4-cycle shown in FIG. 7A. With copy applied to it, the 4-cycle shown in FIG. 7A may be expanded to either an 8-cycle as shown in FIG. 7B or a 12-cycle shown in FIG. 7C depending on choices for the connections of the original X stabilizers. If the cycle structure of the input is known, selectively assigning edges can be used to lengthen short cycles of the original graph. On the other hand, an identical copy of the Z stabilizers is imposed on every variable node in the repetition code, leading to many new 4-cycles as shown in FIG. 7D, where the bold lines show the three new 4-cycles in Z from the two Z stabilizers that shared the same variable node. A counting argument shows the following.

### Lemma 6

Splitting a variable node into s variable nodes during copying introduces

$$( \begin{matrix}s \\ 2\end{matrix} ) ( \begin{matrix}c \\ 2\end{matrix} )$$

new 4-cycles in the Z-only Tanner graph and c(s−1) new 4-cycles between X and Z, where c is the number of Z check nodes connected to the original variable node.

Note that this lemma applies to both the original and the modified copying procedures described above. For example, by applying Lemma 6 to the 15-qubit Reed-Muller code in Equation (14), Hastings's copying produces 738Z+168X−Z=906 new 4-cycles; the reduced copying produces 468Z+96X−Z=564 new 4cycles; and the targeted copying with targ_{q}_{_{X}}=3 produces 45Z+10X−Z=55 new 4-cycles.

Similar to copying, gauging only modifies the length of the X cycles, while new 4-cycles are created in both Z and between X and Z. Although the number of each is unpredictable due to the nature of the new Z stabilizers, it is often significant due to the density of the solution.

The terms H_{X}⊗ [symbol] ,

$${H}_{X}^{T} ⊗ {I}_{ℓ - 1} ,$$

and H_{Z}⊗ [symbol] in thickening make copies of each X or Z cycle present up to this point in the procedure. Additionally, \tilde{H}_{Z} contains both H_{X} and H_{Z}, converting cycles between X and Z to purely Z cycles. These new cycles are connected through a copy of the repetition code in Iₙ⊗ [symbol] and are therefore potentially lengthened as shown in FIG. 3C. Choosing heights may remove some of the cycles from the H_{Z}⊗ [symbol] term.

Every edge of the graph Qᵢ→X₁ generates an X-Z 4-cycle in the resulting code but exactly half of that number are removed by deleting Zᵢ. Every multiedge in Qᵢ→Xᵢ results in a Z 4-cycle. Any two cycle basis elements that share two edges in Xᵢ→ [symbol] ᵢ leads to an X 4-cycle. Cellulation results in new X-Z 4-cycles. In embodiments where thickening is performed to reduce q_{X} after coning, then the terms H_{X}⊗ [symbol] ,

$${H}_{X}^{T} ⊗ {I}_{ℓ - 1} ,$$

and H_{Z}⊗ [symbol] as described above should be applied.

Accordingly, the number of new short cycles introduced by quantum weight reduction may severely degrade the performance of iterative decoding schemes based on the Tanner graph, requiring cycle-mitigation techniques or expensive postprocessing such as ordered-statistics decoding (OSD).

### III. CLASSICAL WEIGHT REDUCTION

The construction of a weight-reduced error correction method in accordance with one aspect of the present disclosure and its application to reduce stabilizer weight in the context of quantum product codes is described herein. In one or aspects, the weight-reduced error correction code provided herein is a procedure that is relatively simple and maintains or increases the (classical) minimum distance. For clarity, the present disclosure refers to Hastings's work as quantum weight reduction and the method described herein as classical weight reduction.

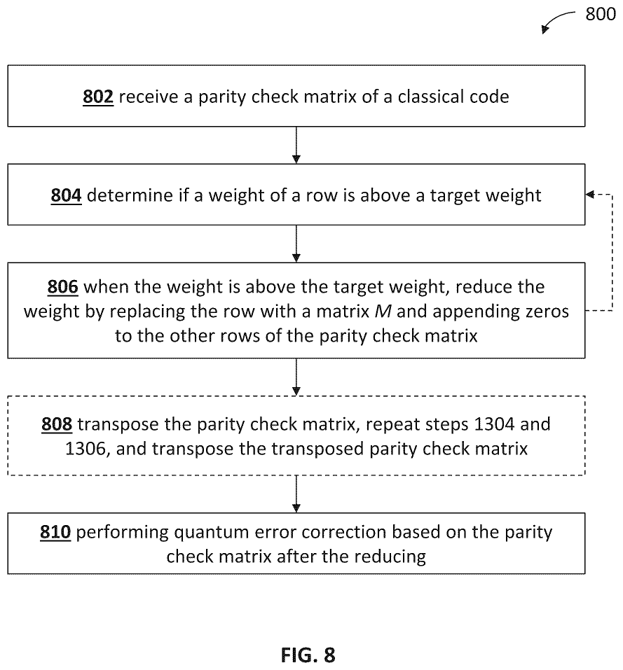

FIG. 8 shows a flowchart of a method 800 in accordance with an embodiment of the present disclosure for constructing a weight-reduced quantum error correction code.

At step 802, a full-rank, (n−k)×n parity check matrix H of a classical code C with rows {hᵢ} is received. In some embodiments, the code C may be a LDPC code. The classical [n,k,d] linear code C=C(H) associated with H is the sub-space orthogonal to the row space of H with respect to the standard Euclidean inner product

$$C = \{ v ∈ {𝔽}_{2}^{n} \vert {H}_{v}^{T} = 0 \} ,$$

where v=(v₁, . . . , vₙ) is a row vector, and superscript T is the standard matrix transpose. The support of v is the set supp(v)={i|vᵢ≠0}. In the present context, the parity check matrix H of the code C serves a role similar to stabilizers in QEC with each row of the check matrix serving as a QEC stabilizer. The minimum distance (also referred to as the Hamming distance) of the code, a metric of the error resistance of the code, is given by d=min{wt(v)|0≠v≠C}, where wt=supp(v)| denotes the Hamming weight.

At step 804, it is determined if the weight w of a particular row of H is above a target weight threshold x, causing the row to be a candidate for weight reduction.

In the quantum context, an [symbol] n,k,d [symbol] Pauli stabilizer code is described numerically by its stabilizer matrix in symplectic form whose first n columns denote Pauli X operators and subsequent n columns Pauli denote Z operators. CSS codes can be described by two matrices H_{X} and H_{Z} of n columns corresponding to the X and Z stabilizer generators, respectively, such that the stabilizer matrix H is of the form H_{X} ⊕H_{Z}. The inputs of a procedure acting on a set of stabilizers appears as H_{X} and H_{Z} and the outputs appear with tildes, \tilde{H}_{X} and \tilde{H}_{Z}. Let n_{X} and n_{Z} be the number of X and Z stabilizers, respectively, w_{X} and w_{Z} be the maximum Hamming weight of the X and Z stabilizer generators, respectively, and q_{X} and q_{Z} be the maximum Hamming weight of the columns of H_{X} and H_{Z}, respectively. The parameters q_{X} and q_{Z} are sometimes known as the X- and Z-qubit degrees, respectively, as, for example, q_{X} denotes the maximum number of stabilizer generators that have nontrivial support on the same qubit. Note that these parameters are not inherent to the method disclosed herein but are relative to the specific form of the generators chosen.

Hypergraph product codes, HGP(H₁,H₂), are CSS codes constructed from two parity-check matrices H₁ and H₂ with stabilizers in the form of shown in Equation (1):

$${H}_{X} = ( {H}_{1} ⊗ \begin{matrix}I & I ⊗ {H}_{2}^{T}\end{matrix} ) , {H}_{Z} = ( I ⊗ {H}_{2} {H}_{1}^{T} ⊗ I )$$

Due to the identities, the row and columns weights are completely determined by the classical inputs: w_{X}=w₁+q₂, q_{X}=max(q₁, w₂), w_{Z}=w₂+q₁, and q_{Z}=max(q₂, w₁). For the parity-check matrix H with rows {hᵢ}, let wᵢ=wt(hᵢ) be the weight of the i-th row, and let q₁ be the weight of the i-th column. The row weight is indicative of the code weight or the number of qubits involved in each stabilizer check, and the column weight is indicative of the qubit degree, or the number of checks each qubit participates in.

The goal is then to convert the received check matrix H into a modified check matrix H where the weight of each row, or stabilizer, is reduced from w_{X} to less than or equal a threshold value without increasing q_{X}, and vice versa for column weight without impacting row weight. At step 806, for each row that was identified in step 804 that exceeded the threshold weight value, the row is modified to reduce its weight. Consider a row hᵢ with wᵢ>x, where x is the threshold weight value, and assume that the support of hᵢ has been permuted to the first wᵢ bits {v₁, . . . , v_{w}}. Then to reduce the row weight in accordance with one embodiment of the present disclosure, for each such row, w−1 new qubits are introduced,

$$\{ {v}_{1}^{′} , … , {v}_{w - 1}^{′} \} .$$

This introduces wᵢ−1 new columns to the check matrix H and the row hᵢ is replaced with

$$( \begin{matrix}{I}_{{w}_{i}} & 0 & {H}_{{w}_{i} - 1}^{T}\end{matrix} ) ,$$

where I_{w}_{ᵢ} is the wᵢ×wᵢ identity matrix, 0 represents the rest of the original columns not in the support of hᵢ, and

$${H}_{{w}_{i}}^{T}$$

is the transpose of the parity-check matrix for the [l, 1,l] classical repetition code Hₗ in Equation (11), expressed in matrix form are as follows:

$$\begin{matrix}\begin{matrix}{v}_{1} & … & {v}_{w}\end{matrix} \\ ( \begin{matrix}1 & … & 1 & 0 & 0 & 0\end{matrix} )\end{matrix} ↦ \begin{matrix}\begin{matrix}{v}_{1} & {v}_{2} & … & {v}_{w - 1} & {v}_{w} & & {v}_{1}^{′} & {v}_{2}^{′} & … & {v}_{w - 2}^{′} & {v}_{w - 1}^{′}\end{matrix} \\ ( \begin{matrix}1 & … & & & & … & 1 & & & & \\ & 1 & & & & … & 1 & 1 & & & \\ & & ⋱ & & & … & & & ⋱ & & \\ & & & 1 & & … & & & & 1 & 1 \\ & & & & 1 & … & & & & & 1\end{matrix} )\end{matrix} \qquad Equation ( 28 )$$

As shown, the resulting matrix may be conceptualized as being composed of two sub-matrices, the first sub-matrix is comprised of columns v₁ to v_{w} and the second sub-matrix is comprised of columns

$${v}_{1}^{′}$$

to columns

$${v}_{w - 1}^{′} .$$

Each column v of the first submatrix is to have a weight of 1 where the corresponding entry of the row hᵢ is 1, and a weight of 0 otherwise. The second submatrix comprises the appended columns where each column of the (w−1) columns having a non-zero even-numbered weight and each row of the w rows of the second sub-matrix having a weight of less than or equal to the value by which the row weight exceeded the target weight threshold (w₁−x), wᵢ being equal to the weight of a corresponding row of the first sub-matrix. The resulting check matrix is a sparse matrix with 0's everywhere else. The row weight reduction would be performed for all rows where the row weight exceeds the threshold weight value. Steps 804 and 806 are repeated for all rows of the check matrix that need to be reduced.

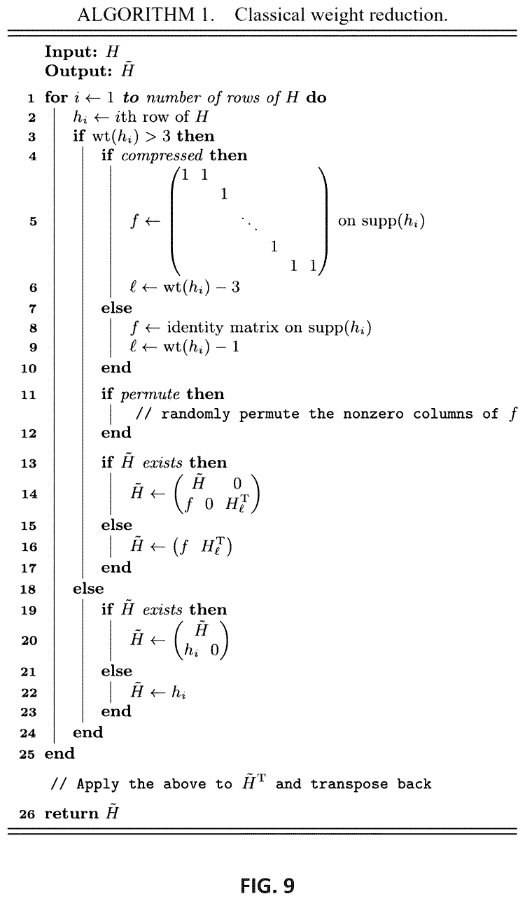

Optionally at step 808, to optimize the column weights q_{X}, the modified parity check matrix \tilde{H} generated in step 804 is transposed with step 804 repeated on \tilde{H} based on a column weight threshold value. After transposing the resulting matrix, there is provided a modified parity-check matrix that is both row weight-reduced and column weight-reduced. FIG. 9 illustrates a pseudo-code Algorithm 1 that may be used to implement the foregoing steps.

Equation (28) differs slightly from Equation (10) as noted by the location of the “1”s on the right hand side in both equation, which mean an increase in the (classical) minimum distance of the reduced code at the cost of a decreased encoding rate.

### Theorem 1

Let H be the parity-check matrix of an [n,k,d] binary linear code, let w_{H} be the maximum row weight of H, and let q_{H} be the maximum column weight of H. Then, Algorithm 1 outputs a parity-check matrix \tilde{H} with w_{\tilde{H}}=q_{\tilde{H}}=3, the code of which has parameters [O(nρ),k,\tilde{d}], where ρ=max{w_{H},q_{H}} and \tilde{d}≥d. Additionally,
(a) if all rows of H have weight greater than three, then \tilde{d}≥3d/2;
(b) if all columns of H have weight greater than three, then

$$\tilde{d} \geq d {min}_{i} {q}_{i} ;$$

(c) if all rows and all columns of H have weight greater than three, then

$$\tilde{d} \geq ( 3 d {min}_{i} {q}_{i} ) / 2.$$

Proof. The claims about w_{H},q_{H}, and the length flows from Equation (28). Weight reducing a row does not change column weights and vice versa, so its implementation of one does not undermine the other. Reducing a row or a column appends the same number of linearly independent rows as columns, so the rank is always preserved.

Let H be a parity-check matrix with rows {h₁, . . . , hₙ₋ₖ}. Reducing row hᵢ produces the parity-check matrix:

$$( \begin{matrix}{h}_{1} & \\ ⋮ & 0 \\ {h}_{i - 1} & \\ f & {H}_{{w}_{i}}^{T} \\ {h}_{i + 1} & \\ ⋮ & 0 \\ {h}_{n - k} & \end{matrix} ) \qquad ( 29 )$$

where wᵢ=|supp hᵢ| is the weight of row i and f|_{supp h}_{ᵢ}=I_{w}_{ᵢ} is the wᵢ×wᵢ identity. Denoting the columns to the left of the vertical line by “old” and those to the right by “new”, f|_{old supp h}_{ᵢ}=0. If c is a codeword of Equation (29), then c|_{old} satisfies the checks hⱼ for j≠i and

$$( \begin{matrix}f & {H}_{{w}_{i} - 1}^{T}\end{matrix} ) c = 0.$$

### Then,

$$0 = ( \begin{matrix}f & {H}_{{w}_{i} - 1}^{T}\end{matrix} ) c = ( \begin{matrix}f & {H}_{{w}_{i} - 1}^{T}\end{matrix} ) ( \begin{matrix}c {\vert}_{old} \\ c {\vert}_{new}\end{matrix} ) = fc {\vert}_{old} + {H}_{{w}_{i} - 1}^{T} c {\vert}_{new}$$

gives

$${H}_{{w}_{i} - 1}^{T} c {\vert}_{new} = fc {\vert}_{old} = c {\vert}_{supp {h}_{i}} .$$

The image of

$${H}_{{w}_{i} - 1}^{T}$$

includes even-weighted vectors, so c|_{supp h}_{ᵢ} has even weight and therefore c|_{old} satisfies hᵢ. Hence, c|_{old} is a codeword of the original code.

Suppose that c is a codeword of Equation (28) such that c|_{old}=0. Then,

$${H}_{{w}_{i} - 1}^{T} c {\vert}_{n e w} = 0.$$

### However, ker

$${H}_{{w}_{i} - 1}^{T} = 0 ,$$

which means c|_{new}=0. Therefore, there is a one-to-one correspondence between codewords of the original code and codewords of Equation (28), or \tilde{k}=k. It also follows that the minimum-weight codeword of Equation (28) is at least as large as the old code, or \tilde{d}≥d.

Then to prove Theorem 1(a) stated above, assume that wᵢ>3 for all 1≤i≤n−k and weight reduce all rows. A codeword c has wt(c|_{old})≥d and fc|_{old} flips at least d syndromes. A single “1” in c|_{new} flips two syndromes, so at least d/2 “1”s are required to make c commute: wt(c)=wt(c|_{old})+wt(c|_{new})≥d+d/2=3d/2.

To prove Theorem 1(b), observe that any bit of the original code that is supported on a column that is expanded must now have support on the full repetition code in the expanded section, as this is the only way to commute with the newly added rows. This increases the weight of any codeword supported on this bit; however, not all minimum-weight codewords may have support here, so the minimum distance may not increase. If all columns are expanded, the distance increases by at least a multiplicative factor of the smallest column weight.

Theorem 1(c) may be proven by combining (a) and (b).

Note that the proof does not assume that H is full rank and therefore the proof holds for parity-check matrices with redundant checks.

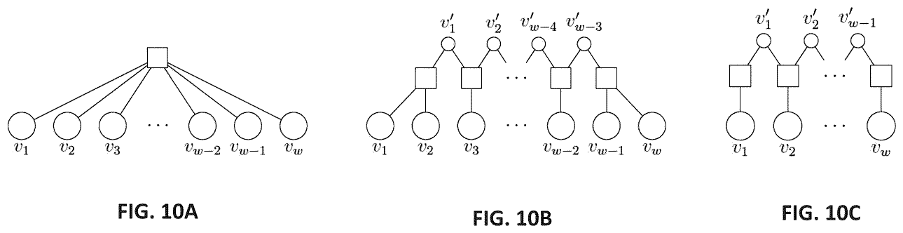

Performing weight reduction using Equation (10) (gauging) rather than Equation (28) is referred to, by comparing the two forms of f, as compressed classical weight reduction, since it requires the addition of fewer additional bits. In this case, the condition \tilde{d}≥d still holds true but now part (a) of the proof no longer holds. Consider a codeword with overlap of two with the check being reduced such that the overlap falls within a single row of the expansion f and it may be discerned that a generalized proof of part (a) would fail. Thus, Theorem 2 below presents the theoretical guarantees of this method; the proof is a simple modification of Theorem 1. FIG. 10A shows an example Tanner graph with qubits v₁ to v_{w} supporting a check node (square). FIG. 10B shows the result of applying compressed classical weight reduction to the check node in FIG. 10A. FIG. 10C shows the result of the classical weight reduction of the check node form FIG. 10A. It is noted that FIGS. 10A and 10B are the same as FIGS. 2A and 2B.

### Theorem 2

Let H be the parity-check matrix of an [n,k,d] binary linear code with maximum row and column weights of H, w_{H} and q_{H}, respectively. Then, Algorithm 1 using compressed classical weight reduction outputs a parity-check matrix \tilde{H} with W_{\tilde{H}}=q_{\tilde{H}}=3, the code of which has parameters [O(nρ),k,\tilde{d}], where ρ=max{w_{H},q_{H}}−2 and

$$\tilde{d} \geq d max \{ 1 , {min}_{i} ( {q}_{i} - 2 ) \} .$$

Note that the factor

$$max \{ 1 , {min}_{i} ( {q}_{i} - 2 ) \}$$

in Theorem 2 is the minimum number of columns that any individual column is expanded to under compressed weight reduction.

In general, there are many possible choices of row expansions. For example, any choice of f with weight one in columns corresponding to the support of the check being reduced and weight zero columns elsewhere may be considered a valid expansion. However, not all such choices of f may not result in effective weight reduction. Further increasing the number of columns of

$${H}_{{w}_{i} - 1}^{T}$$

may induce an additive constant to the distance but at the expense of a nearly linear increase in n. A row hᵢ can be expanded to

$$( \begin{matrix}f & {H}_{{r}_{i} - 1}^{T}\end{matrix} )$$

where f is any rᵢ×n matrix with column weight one on bits of the support of hᵢ and column weight zero elsewhere. In this case, if f has any row with weight greater than one, then part (a) of Theorem 1 cannot be generalized to this choice of f and, instead, the guarantee is that reduction will never reduce the minimum distance. Applying this to the transpose results in column expansion and if all columns are expanded, then the minimum distance further increases by a factor of at least the minimum size of all column expansions.

The classical weight reduction method described herein may also be used in the context of generalized distance balancing. This is the tensor product of the chain complex of an [symbol] n,k,d [symbol] CSS code with stabilizer matrices H_{X} and H_{Z} and the co-chain complex of an [n_{c},kₑ,dₑ] classical code with parity-check matrix H_{c}. The resulting stabilizers are the same as thickening but with H replaced by H_{c}:

$${\tilde{H}}_{X} = ( \begin{matrix}{H}_{X} ⊗ {I}_{{n}_{c}} & {I}_{{n}_{X}} ⊗ {H}_{c}^{T}\end{matrix} ) , \qquad ( 30 )$$

$${\tilde{H}}_{Z} = ( \begin{matrix}{H}_{Z} ⊗ {I}_{{n}_{c}} & 0 \\ {I}_{n} ⊗ {H}_{c} & {H}_{X}^{T} ⊗ {I}_{{n}_{c} - {k}_{n}}\end{matrix} ) .$$

The code has dimension \tilde{k}=kk_{c} and distances \tilde{d}_{X}=d_{c}d_{X} and \tilde{d}_{Z}=d_{Z}. In the general case, if H_{c} has maximum row and column weights w and q, respectively, then Equation (30) has parameters \tilde{w}_{X}=w_{X}+q, \tilde{q}_{X}=max{q_{X},w}, \tilde{w}_{Z}=max{w_{Z}+q, q_{X}}, and \tilde{q}=max{q_{Z}+q,w_{X}}. Weight reducing H_{c} before using Equation (30) sets w=q=3. This could be used as a replacement for thickening, although other classical codes with dimension one are most likely not as useful as the repetition code. In this case, there may be kₑ heights to choose from, which can add a maximum of three to the column weight (due to I⊗H_{c}).

### A. Decoding

At step 810, quantum error correction is performed based on the weight reduced check matrix by a decoder of the quantum processing unit (QPU). Unlike the quantum weight reduction, the classical weight reduction method described herein may be able to map back onto the original code in a more straightforward manner. The proof of Theorem 1 provided herein may be used to map the decoding problem of the weight-reduced code back to the decoding problem of the original code. Suppose that the weight-reduced parity-check matrix is used to decode. An error on the bits corresponding to weight-reduced columns can be uniquely identified and corrected using the rows corresponding to the H^{T} blocks. Collapsing these columns into a single bit puts the matrix into the form “original bits” followed by “new bits”. The original bits are protected by the original parity-check matrix and the original decoder may be used. Errors on the new bits may be corrected using the H^{T} blocks. Message-passing-based decoders may perform better on the weight-reduced code than the original code.

Graphically, a high-degree node shown in FIG. 10A is replaced by the weight reduce node shown in FIG. 10C, which has no cycles and lengthens any cycles of which the original node was previously a part. The exact increase in cycle length depends on the ordering of the initial edges. Take the length-two path from v_{w-1} to v_{w} in FIG. 10A for example, it becomes a length-four path through v_{w-1},

$${v}_{w - 1}^{′} ,$$

and v_{w}, while the length-two path from v₁ to v_{w} becomes a length−(2w+1) path through v₁,

$${v}_{1}^{′} , {v}_{2}^{′} , … , {v}_{w - 1}^{′} ,$$

and v_{w}. If the cycle structure of the input code is known, permutations of the check sides of the original edges in the weight reduced Tanner graph can be used to selectively increase harmful short cycles. These permutations are the graphical representation of the permutations described in Section B below.

Increases in girth (the length of a shortest cycle contained in the graph) and improvements in iterative decoder performance using this approach has been observed. Recall the unique-neighbor property of expander codes as described more fully in “The Sipser-Spielman Construction” by P. Shankar in Resonance 10, 25 (2005), the entire disclosure of which is incorporated herein in its entirety. Consider a ( [symbol] ,r,ε, [symbol] /2)-left expander with vertex bipartition L∪R, (for all sets S⊂L of size no more than ε|L|,

$$\vert 𝒩 ( S ) \geq \frac{ℓ}{2 \vert S \vert} \vert ,$$

where [symbol] (S) is the neighborhood of S). Then for these sets, ∃y∈R such that | [symbol] (y)∩S|=1, or in other words there exists a unique neighbor. Assume that S is a trapping set, then, unless there are many such y values, there is not going to be a large amount of extrinsic information flowing into this set of nodes to overcome the trapping set. A cycle with extrinsic information introduced into it will be able to overcome what would otherwise become a trapping set. In this context, cycle connectivity may be more important than cycle length for decoder performance.

### B. Permutations

Permutations of the input are also important for reasons besides selectively increasing the girth of the Tanner graph. Consider an [n,k,d] code with parity-check matrix H. Permuting the columns of H produces an equivalent code with the same parameters and corresponds to a relabeling of the Tanner graph without any effect on cycle structure. However, weight reducing the original code and the permuted code may produce nonequivalent codes with potentially different distances. By way of a non-limiting example, consider weight reducing the input:

$$( \begin{matrix}1 & 1 & 1 & 1 & 0 & 0 \\ 0 & 0 & 1 & 1 & 1 & 1\end{matrix} )$$

and its permutated version:

$$( \begin{matrix}1 & 0 & 1 & 0 & 1 & 1 \\ 0 & 1 & 1 & 1 & 1 & 0\end{matrix} )$$

With the same weight reduction method, the following check matrices may be produced:

$$H = ( \begin{matrix}1 & . & . & . & . & . & 1 & . & . & . & . & . \\ . & 1 & . & . & . & . & 1 & 1 & . & . & . & . \\ . & . & 1 & . & . & . & . & 1 & 1 & . & . & . \\ . & . & . & 1 & . & . & . & . & 1 & . & . & . \\ . & . & 1 & . & . & . & . & . & . & 1 & . & . \\ . & . & . & 1 & . & . & . & . & . & 1 & 1 & . \\ . & . & . & . & 1 & . & . & . & . & . & 1 & 1 \\ . & . & . & . & . & 1 & . & . & . & . & . & 1\end{matrix} )$$

$$and$$

$${H}^{′} = ( \begin{matrix}1 & . & . & . & . & . & 1 & . & . & . & . & . \\ . & . & 1 & . & . & . & 1 & 1 & . & . & . & . \\ . & . & . & . & 1 & . & . & 1 & 1 & . & . & . \\ . & . & . & . & . & 1 & . & . & 1 & . & . & . \\ . & 1 & . & . & . & . & . & . & . & 1 & . & . \\ . & . & 1 & . & . & . & . & . & . & 1 & 1 & . \\ . & . & . & 1 & . & . & . & . & . & . & 1 & 1 \\ . & . & . & . & 1 & . & . & . & . & . & . & 1\end{matrix} ) ,$$

respectively. The linear code given by H has parameters [12, 4, 3] and [12, 4, 4] for H′.

More generally,

$$\begin{matrix}( {I}_{{w}_{i}} & 0 & {H}_{{w}_{i} - 1}^{T}\end{matrix} ) ,$$

can be replaced with

$$( \begin{matrix}{\prod }_{{w}_{i}} & 0 & {H}_{{w}_{i} - 1}^{T} )\end{matrix} ,$$

where H is any permutation of the identity. Different permutations can be used for reducing each row and column independently. The positive effect on distance can be seen in the examples shown below. It is noted that the quantum weight reduction method is equally susceptible to permutations. If copying is redefined in terms of concatenation, then a choice of permutation is identical to making the choice of which copied qubits are used to represent X stabilizers. Combined with Theorem 2, the effect of permutations has on gauging becomes evident, and may potentially lead to different code distances. Both copying and gauging may affect cycle length as shown in the Thickening and Choosing Height section herein. Permutations in thickening are equivalent to the twisted homological product, which has been noted to improve distance in other settings.

### Implementation

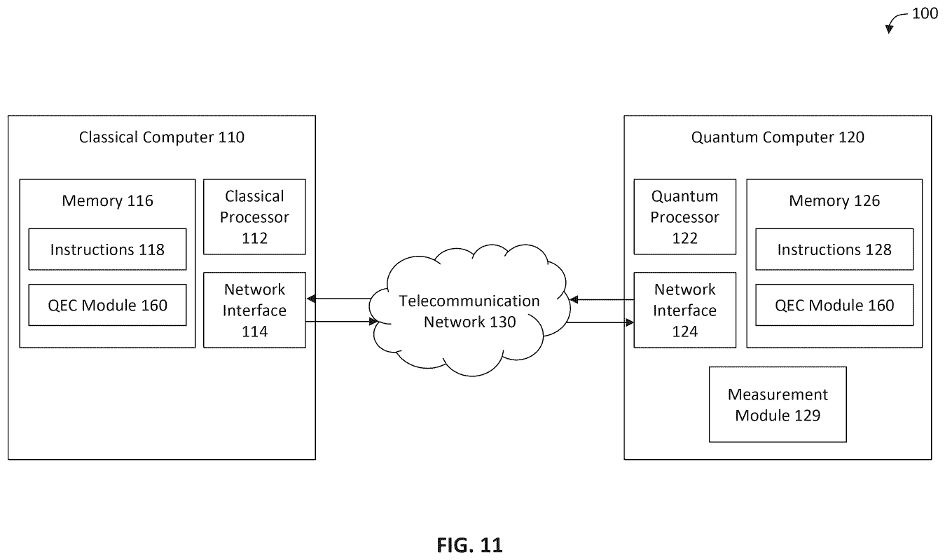

FIG. 11 is a simplified block diagram of an example embodiment of a quantum computing system 100 in accordance with the present disclosure. As shown, system 100 includes one or more classical computers 110 that are operably coupled or in operable communication with one or more quantum computers 120, via a telecommunication network 130.

Each of the classical computer(s) 110 may be configured to perform one or more of the method steps, such as code weight reduction steps, described herein. In some embodiments, each of the classical computers 110 may be, for example, a desktop terminal, a tablet computer, a notebook computer, a server, a cloud end, or any suitable processing system. Other classical computers suitable for implementing embodiments described in the present disclosure may be used, which may include components different from those discussed below. In some examples, the classical computer 110 may be implemented across more than one physical hardware unit, such as in a parallel computing, distributed computing, virtual server, or cloud computing configuration. Although FIG. 11 shows a single instance of each component of the classical computer 110, there may be multiple instances of each component shown.

As shown in FIG. 11, the classical computer 110 may include one or more classical processors 112, such as a central processing unit (CPU) with hardware accelerator, graphics processing unit (GPU), tensor processing unit (TPU), neural processing unit (NPU), microprocessor, digital signal processor, application-specific integrated circuit (ASIC), field-programmable gate array (FPGA), dedicated logic circuitry, dedicated artificial intelligence processor unit, or combinations thereof.

The one or more classical processors 112 are operably coupled to a network interface 114 for wired or wireless communication with the telecommunication network 130 (e.g., an intranet, the Internet, a P2P network, a Wide Area Network (WAN) and/or a Local Area Network (LAN)) to operably communicate with the quantum computers 120 and one or more optional user terminals 140. The network interface 114 may include wired links (e.g., Ethernet cable) and/or wireless links (e.g., one or more antennas) for intra-network and/or inter-network communications. One or more end users may interact with system 100, for example, by inputting or specifying an appropriate noise model, through one or more user terminals 140 or, alternatively, inputting directly into the classical computer 110.

The classical computer 110 may also include one or more non-transitory memories 116 which may include a volatile or non-volatile memory (e.g., a flash memory, a random-access memory (RAM), and/or a read-only memory (ROM)). The non-transitory memory 116 may store instructions 118 for execution by the classical processors 112, for example, instructions to implement/execute a software-based QEC module 160, in whole or in part, as described in further detail below. The memory 116 can also store representations of a noise model (e.g., defined by user via user interaction with user terminal 140). Examples of non-transitory computer-readable media include a RAM, a ROM, an erasable programmable ROM (EPROM), an electrically erasable programmable ROM (EEPROM), a flash memory, a CD-ROM, or other portable memory storage.

Each of the quantum computer(s) 120 includes a quantum processor 122 operably coupled to a memory 126, and a network interface 124 (which is also operably coupled to the memory 126). The memory 126 stores instructions 128 that are executable by the quantum processor 122. The instructions 128 can include, for example, instructions to implement/execute the software-based QEC module 160 in whole or in part. The quantum computer 120 may be based on a suitable form of physical qubit, including superconducting qubits, photonic qubits, trapped-ion qubits, silicon-based qubits, and neutral atoms. The quantum processor 122 includes components for forming quantum entanglements between physical qubits. For example, in a photonic based quantum system, a network of interferometers may be used to entangle, or to “stitch”, input photonic states into, for example, a 3-dimensional lattice structure of a multimode entangled state based on the weight-reduced quantum error correction code described herein. The quantum processor 122 may also be configured to manipulate one or more of the physical properties of the input state by performing quantum operations such as applying unitary transformations using quantum gates. The quantum processor 122 may include a measurement module 129 that includes one or more measurement components (e.g., photon number resolving detectors) configured to measure the output of the quantum processor 122 and provide information about the quantum result. The quantum computer 120 receives input to a quantum simulation process from classical computer 110 and/or user terminal 140 and returns simulation results.

As shown in FIG. 11, the system 100 can be conceptualized as including a QEC module 160, which can be implemented in software, hardware, or a combination thereof. The QEC module 160 may be implemented in full or in part on one or both of the classical computer 110 and quantum computer 120, and hence the two modules are shown in dotted lines in both computers in FIG. 11. For example, in some implementations, the QEC module 160 is implemented in software as part of a classical (non-quantum) computer 110 and output instructions to one or more components of the quantum computer 120, such as entangling or stitching elements, and/or measurement module 129. In some implementations, at least step 810 of the flowchart 800, shown in FIG. 8, is performed on a quantum computer, whereas one or more other steps may be performed on a classical (non-quantum) computer. By way of a non-limiting example, in a continuous variable photonics quantum computing architecture, a QPU may be used to construct a multimode entangled state that is suitable for quantum error correction and perform measurements. The configuration of each QPU may be, at least in part, dependent upon the quantum error correction code to be implemented such as the ones described by the weight reduced check matrices generated in accordance with the methods described herein. The QPU may include interferometers and optical detectors configured to stitch (e.g. forming quantum entanglements) any number of input resource quantum states into a macronode that forms one lattice vertex of a higher-dimensional (e.g. in time domain and spatial domain) multimode entangled state, and to further perform measurement-based quantum computation. The interferometers may be configured into a network such that the resulting state from the network of interferometers is that all input resource states are mutually entangled into a macronode. Measurements can be performed on the macronodes by the optical detectors to provide electric field quadrature information (e.g. the position or amplitude quadrature referred to herein as the “q-quadrature” and the momentum or phase quadrature referred to herein as the “p-quadrature”). In some embodiments, the optical detectors are homodyne detectors which can be used to perform measurements on each macronode to reduce each macronode into single nodes with multiple edges. The measurement outcomes can be used by the QPU to perform error correction and can also be utilized by the system to perform measurement-based quantum computation (MBQC). The homodyne detector may be configured for performing quadrature measurements by interfering the optical modes of an input entangled resource state and the train of local optical pulses on a beamsplitter and detecting the optical power difference of the two beam splitter outputs as an indication of the modal property(ies) of the quantum state of the given optical pulse. The measurement outcomes collected on the multimode entangled states (i.e., at the physical hardware layer) can be processed together to implement one or more aspects of quantum error correction based on the weight reduced check matrices. For example, for a given time step along the time domain, each row of the weight reduced check matrix may correspond to an ancillary qubit (one of the macronodes as described above), each column of the check matrix may correspond to a data qubit (again, that corresponds to a macronode), and for any “1” in a specific row and column of the check matrix, the corresponding macronode(s) are connected by an edge in the form of a quantum entanglement with one of the modes as an input to the macronode corresponding to the row, and the other mode as an input to the macronode corresponding to the column.

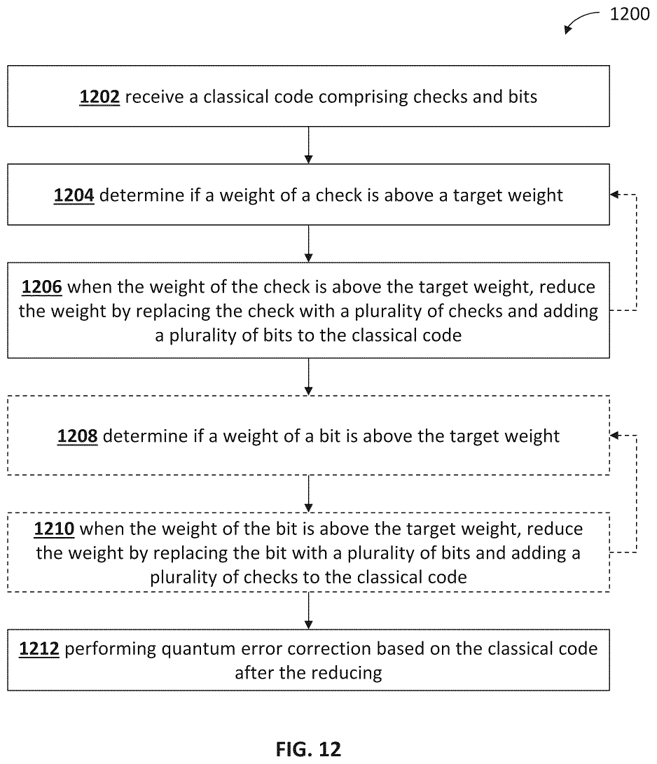

FIG. 12 illustrates a flowchart of a method 1200 in accordance with another embodiment of the present disclosure for constructing a weight-reduced quantum error correction code.

At step 1202, a classical code comprising checks and bits are received.

At step 1204, it is determined if a weight of a check in the received classical code is above a target weight.

At step 1206, when the weight of the check is above the target weight, the weight is reduced by replacing the check with a plurality of checks and adding a plurality of bits to the classical code.

Steps 1204 to 1206 is repeated for each check within the received classical code.

Optionally, at step 1208, it is determined if a weight of a bit is above the target weight.

Optionally, at step 1210, when the weight of the bit is above the target weight, the weight is reduced by replacing the bit with a plurality of bits and adding a plurality of checks to the classical code.

Optional steps 1208 and 1210 may be repeated for each bit of the received classical code.

At step 1212, a quantum error correction code is constructed based on the classical code after reducing the weight.

### IV. EXAMPLES AND NUMERICAL RESULTS

In this section, non-limiting examples of codes constructed using classical and quantum weight reduction are presented. The focus is on two classes of QEC codes: hypergraph-product codes and lifted-product codes for two reasons. First, both classical and quantum weight reduction are applicable to these code classes, so direct comparisons between the two weight-reduction methods can be made. Second, both of these classes contain code families with constant encoding rate and almost linear minimum distance in the case of lifted-product codes, and therefore present compelling alternatives to code families with limited parameters such as two-dimensional topological codes.

For hypergraph-product codes, recall that the distance of a hypergraph-product code HGP(H₁,H₂) is

$$d = min ( {d}_{1} , {d}_{2} , {d}_{1}^{T} , {d}_{2}^{T} ) .$$

If Hᵢ is full rank, then

$$𝒞 ( {H}_{i}^{T} )$$

has k=0. In this case,

$${d}_{i}^{T}$$

is defined to be infinite. By Theorem 1, weight reduction does not decrease the code distance of the (classical) input codes and therefore \tilde{d}≥d, where \tilde{d} is the distance of HGP(H₁,H₂). When specialized to the case of square hypergraph-product codes, HGP(H₁,H₂)=HGP(H,H), where H is the parity check matrix of a linear code. As above, \tilde{H} denotes the matrix produced from H by classical weight reduction and introduce \tilde{H}^{(c)} to denote the matrix produced from H by compressed classical weight reduction. We use [symbol] (H) to denote the code produced from HGP(H) by applying quantum weight reduction.

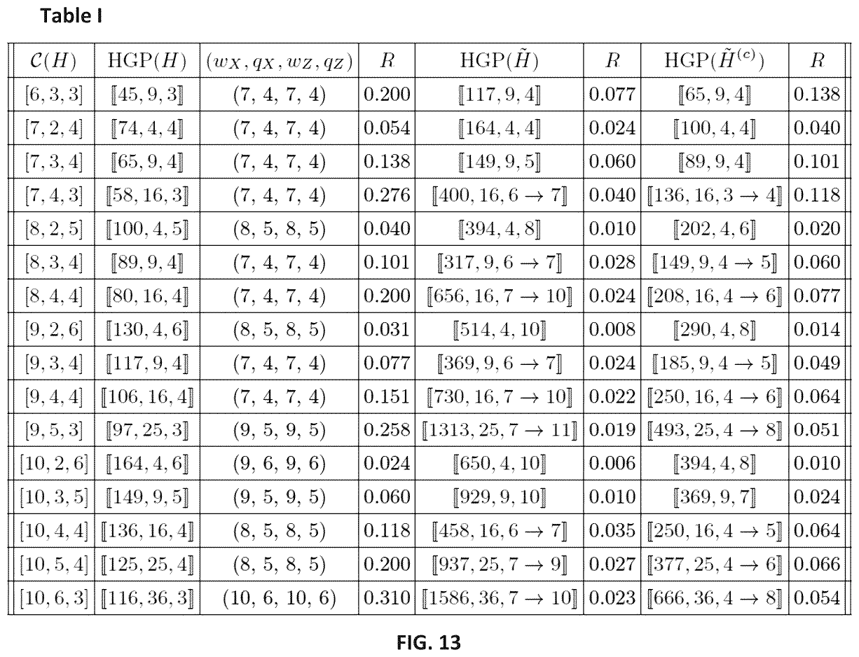

To compare the weight-reduction methods, the GAP function BESTKNOWNLINEARCODE from the GUAVA software package is used as inputs to the hypergraph product, and the small parity-check matrices returned by the weight reduction methods are considered. The results are summarized in Table 1 shown in FIG. 13. In Table 1, [symbol] (H) is the linear code with parity-check matrix H obtained from GAP. For each hypergraph-product code, the encoding rate is set to R=k/n. For each weight-reduction method, the relevant algorithm is applied 10,000 times using different permutations of the input parity-check matrix. In cases in which permutations have improved the distance, we use the notation d₁→d₂, where d₁ indicates the distance without permutations and d₂ indicates the highest obtained distance. The output matrices of classical weight reduction have row and column weights upper bounded by three. All the weight-reduced codes have (\tilde{w}_{X},\tilde{q}_{X},\tilde{w}_{Z},\tilde{w}_{Z})=(6, 3, 6, 3). The weight-reduced codes by the classical weight reduction method may have a higher code distance than their inputs, although at a reduced encoding rate as shown in Table I. It has been observed that the compressed classical weight reduction generates codes with an improved encoding rate but often with a worse distance, as is to be expected from the analysis present in Section III. It has been further observed that independent row and column permutations can dramatically improve the distance of the weight-reduced codes as shown in Table I for the hypergraph-product codes where the number to the left of an arrow is the distance in the unpermuted case and the number to the right is the highest distance found amongst 10,000 codes constructed with independent row and column permutations.

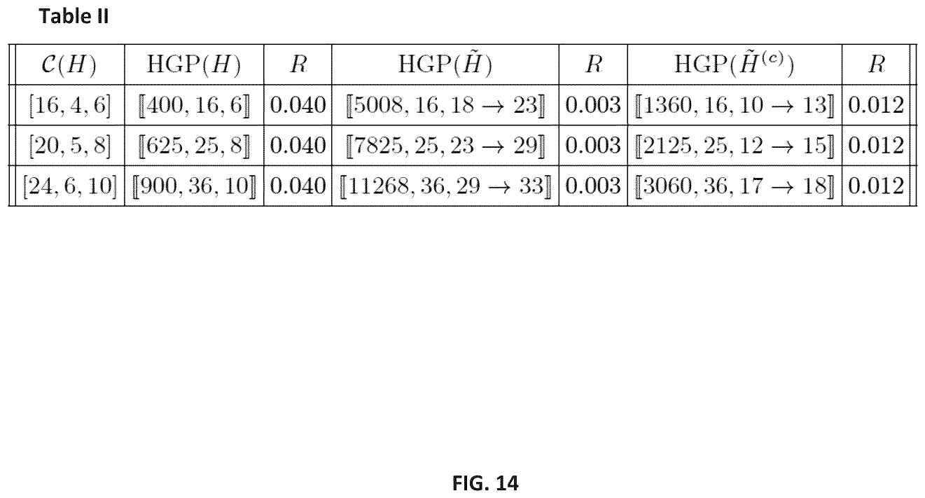

The same methodology was applied to the family of (w_{X},q_{X},w_{Z},q_{Z})=(7, 4, 7, 4) hypergraph-product codes from Table 1 of “Decoding across the quantum low-density parity-check code landscape”, by J. Roffe et. al. Phys. Rev. Res. 2, 043423 (2020), the entire disclosure of which is incorporated herein by reference in its entirety, the results are summarized in Table II shown in FIG. 14. For each hypergraph-product code, its encoding rate is set to R=k/n. For each weight-reduction method, the relevant algorithm was applied 10,000 times using different permutations of the input parity-check matrix. Again, the notation d₁→d₂ is used, where d₁ indicates the distance without permutations and d₂ indicates the highest obtained distance. All the weight-reduced codes have (\tilde{w}_{X},\tilde{q}_{X},\tilde{w}_{Z},\tilde{w}_{Z})=(6, 3, 6, 3). Trends observed in Table I with respect to encoding rate and code distance are similarly observed in Table II.

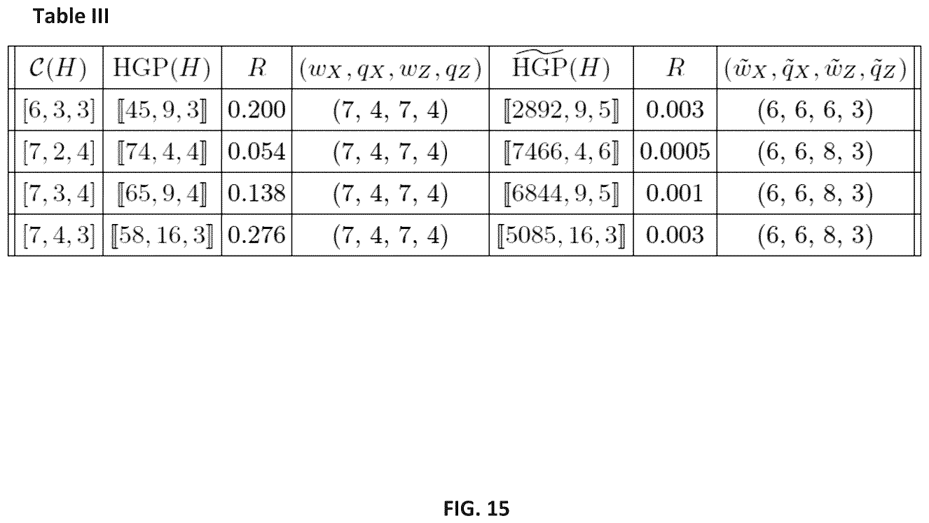

For quantum weight reduction with targ_{qX}=3, parameters of (\tilde{w}_{X},\tilde{q}_{X},\tilde{w}_{Z},\tilde{w}_{Z})=(6, 6, 6, 3) was generated but at the cost of a prohibitively large increase in the number of physical qubits as may be observed in Table III shown in FIG. 15. For example, consider the code HGP(H), where H is the parity-check matrix of the [6, 3, 3] code from Table I. This is a [symbol] 45, 9, 3 [symbol] code with (w_{X},q_{X},w_{Z},q_{Z})=(7, 4, 7, 4). The best weight reduced code generated by applying the quantum weight reduction method after approximately 100 random cycle bases has parameters [symbol] 2892, 9, 5 [symbol] and (\tilde{w}_{X},\tilde{q}_{X},\tilde{w}_{Z},\tilde{w}_{Z})=(6, 6, 6, 3). A second round of thickening and choosing heights was not utilized to reduce \tilde{q}_{X}, as the increase in n was already excessively large. Compare this with the code with parameters [symbol] 117, 9, 4 [symbol] and (\tilde{w}_{X},\tilde{q}_{X},\tilde{w}_{Z},\tilde{w}_{Z})=(6, 3, 6, 3) produced by applying the classical weight reduction method described herein. These disparities combined with the expected degradation of iterative decoding performance in the case of quantum weight reduction as described in Section III.C leads to the conclusion that the classical weight reduction method described herein may provide better performance metrics for weight-reducing hypergraph-product codes.

The more efficient lifted-product construction was also examined. Classical weight reduction is applicable to quasi-cyclic lifted-product codes with various inputs including group algebras and polynomial rings, e.g.

$$( \begin{matrix}{g}_{1} ( x ) & … & {g}_{w} ( x ) & 0 & … & 0 ) ↦\end{matrix} ( \begin{matrix}{g}_{1} ( x ) & & & & & … & 1 & & & & \\ & {g}_{2} ( x ) & & & & … & 1 & 1 & & & \\ & & ⋱ & & & … & & & ⋱ & & \\ & & & {g}_{w - 1} ( x ) & & … & & & & 1 & 1 \\ & & & & {g}_{w} ( x ) & … & & & & & 1\end{matrix} ) \qquad ( 31 )$$

where 1 is the constant polynomial. Although this reduces the row weight, the final weight is still determined by the number of coefficients in each polynomial and could be larger than our target of three.

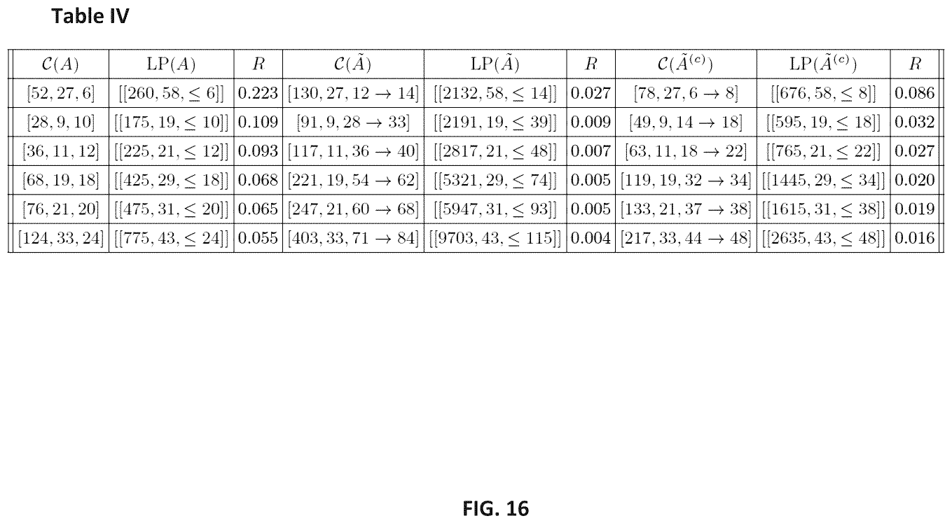

The examples herein are limited to codes of the form LP(A)=LP(A,A^{T}) and use base matrices that have previously appeared in the known academic literature. All of the weight-reduced lifted codes have (\tilde{w}_{X},\tilde{q}_{X},\tilde{w}_{Z},\tilde{w}_{Z})=(6, 3, 6, 3). As with hypergraph product codes, it can be overserved that the weight-reduced codes have higher distance but lower encoding rate than the input codes as shown in Table IV from FIG. 16. It may be further observed that independent row and column permutations improve the distances of the weight-reduced codes. It is noted that ten codes were constructed for each base matrix as the distance calculations are more time-consuming in this case. The upper bounds on the distances are computed using the BP+OSD method described in the academic article “High-threshold and low-overhead fault-tolerant quantum memory” by S. Bravyi et. al., arXiv:2308.07915, the entire disclosure of which is incorporated herein in its entirety. Note that the bounds for the codes produced with (uncompressed) classical weight reduction are likely loose.

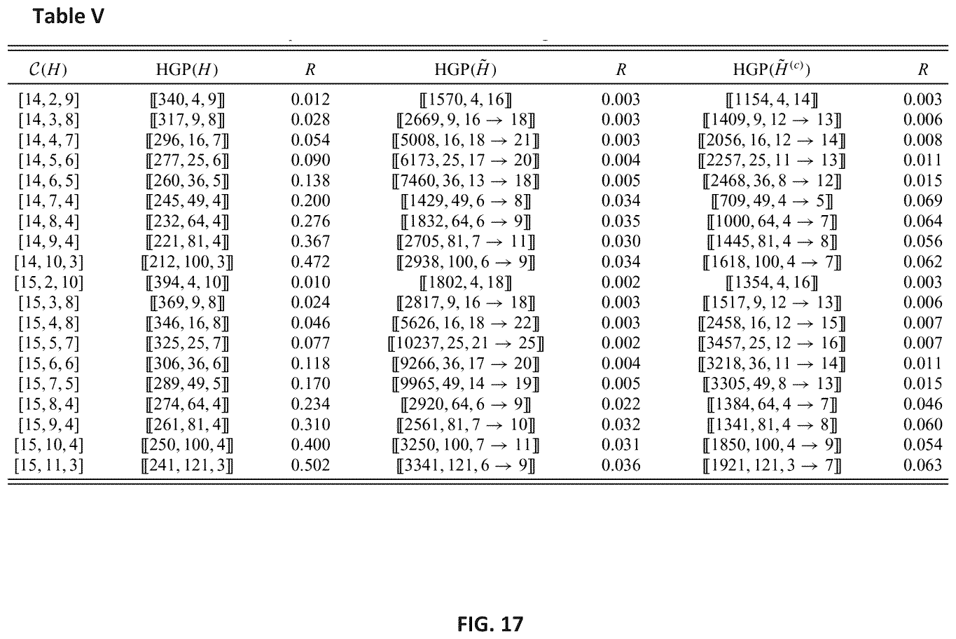

Comparing the weight-reduced lifted-product and hypergraph-product codes generated by methods described herein, it can be observed that both families have similar encoding rates but that the lifted-product codes generally offer improved distances. To illustrate this, consider the quantity Rd², which is equal to one for the rotated surface code. For the hypergraph-product codes, the highest value obtained is Rd²=6.4 for the [symbol] 850, 100, 9 [symbol] code in Table V shown in FIG. 17. In contrast, for the lifted-product codes produced using compressed classical weight reduction method described herein, values up to Rd²=37.6 for the [symbol] 2635,43, ≤48 [symbol] code have been obtained from Table IV.

### A. Numerical Simulations

It is noted that the simulations performed are meant to demonstrate performance of one or more aspects of the present disclosure and are not meant to be limiting in any way. The performance of the codes generated from the classical weight reduction method described herein is simulated as a quantum memory using a noise model. For example, the noise model may be derived from a photonic quantum computing architecture based on GKP qubits as described more fully in “Blueprint for a scalable photonic fault-tolerant quantum computer” by J. E. Bourassa et. al., Quantum 5, 392 (2021) [Blueprint paper] and “Fault-tolerant quantum computation with static linear optics” by I. Tzitrin et. al., PRX Quantum 2, 040353 (2021) [Fault-tolerance paper], the disclosures of which are incorporated herein in their entireties. Specifically, consider a cluster state formed by foliating a QEC code, which is realized using GKP qubits and passive linear optics. For a QEC code with weights (w_{X},q_{X},w_{Z},q_{Z}), the data and ancilla nodes of the corresponding cluster state have degrees q_{X}+2 and w_{X}, respectively, in primal layers and q_{Z}+2 and w_{Z} in dual layers. The foliated stabilizers have weight w_{X}+2 and w_{Z}+2, although these are reconstructed from single-qubit measurement outcomes rather than from being measured directly. Simulation uses 2d foliation layers, where dis the distance of the QEC code.

Following the Fault-tolerance paper, once the cluster state is specified, the resource-state construction involves the following:
(a) Preparing GKP two-qubit cluster states. These cluster states can be constructed using two GKP sensor states, a 50:50 beam splitter, and a π/2 phase shifter. Prior to the beam splitter, each mode is assumed to be a perfect GKP qubit up to a single-mode Gaussian blurring channel parametrized by a variance σ². For Gaussian blurring channels, it is convenient to express the variance of the Gaussian in terms of decibels,

$$( \frac{{σ}^{2}}{{σ}_{v a c}^{2}} ) [ dB ] = - 10 {log}_{10} ( \frac{{σ}^{2}}{{σ}_{v a c}^{2}} ) ,$$

where

$${σ}_{v a c}^{2}$$

is the variance of the vacuum, which is ½ in units where h=1. This model is equivalent to uniform photon loss experienced throughout the cluster-state generation and measurement process.
(b) Placing GKP pairs. Place one GKP cluster-state pair for each edge of the cluster-state graph so that each original node in the cluster state is associated with one mode (half of a pair) per neighbor. This collection of modes is referred to as a macronode.
(c) Measuring macronodes. To measure a given cluster state site in the X basis, a continuous-variable GHZ measurement is applied on each mode within the corresponding macronode. This can be achieved by sending each mode through a beam-splitter network, followed by measurement of momentum on a single mode and position on the rest. To measure in the Z basis, the process is the same except that all modes are measured in the position basis. The Pauli error rate of these measurements increases monotonically with variance σ², which corresponds to decreasing

$$( {σ}^{2} / {σ}_{v a c}^{2} ) [ dB ] .$$

(d) Applying feedforward corrections. As described in the Fault-tolerance paper, feedforward corrective displacement operators that are conditioned on binned homodyne outcomes from a given macronode must be applied on all modes residing in macronodes that are neighbors with respect to the original cluster-state graph. These corrections can be applied in postprocessing with no physical displacement gates are required.

The binning strategy described in the Fault-tolerance paper is adopted as a soft-in-soft-out inner decoder and BP+OSD as a soft-in-hard-out outer decoder. The min-sum variant of BP with N/10 iterations (where Nis the number of qubits in the foliated cluster state) and a flooding schedule are used. For OSD, the combination sweep strategy is chosen with search depth parameter λ=60. The decoder is not optimized to take the structure of the generated weight reduced codes into account.

The performance of the foliated codes is quantified using the logical error rate, which is estimated using Monte Carlo simulations. A logical error is considered to have occurred if any logical qubit has an error after decoding. For nₜₒₜ trials and n_{fail} logical errors, the logical error rate is computed according to

$${p}_{fail} = \frac{{n}_{fail} + {k}^{2} / 2}{{n}_{tot} + {k}^{2}} \qquad ( 32 )$$

with error bars given by

$$k \sqrt{\frac{{p}_{fail} ( 1 - {p}_{fail} )}{{n}_{tot} + {k}^{2}}} \qquad ( 33 )$$

where κ is the desired quantile of a standard normal distribution. For the simulations, κ=1.96, which corresponds to a 95% confidence interval.

A single hypergraph-product code, the [symbol] 45, 9, 3 [symbol] code from Table I, constructed from the parity check H of a [6, 3, 3] linear code is used. The performance of HGP(H) is compared with the performance of the following:
(i) the [symbol] 2892, 9, 5 [symbol] code [symbol] (H), formed by applying quantum weight reduction to HGP(H);
(ii) the hypergraph-product code HGP(H) with parameters [symbol] 17, 9, 4 [symbol] ; and
(iii) the hypergraph-product code HGP(\tilde{H}^{(c)}) with parameters [symbol] 65, 9, 4 [symbol] .

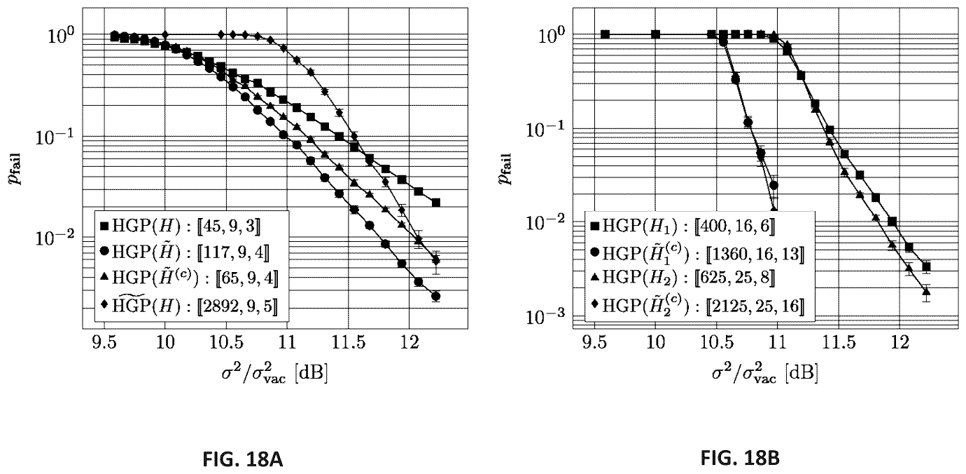

The results are shown in FIG. 18A. Recall that larger values of

$${σ}^{2} / {σ}_{v a c}^{2} [ dB ]$$

corresponds to lower effective Pauli error rates. In FIG. 18A The baseline is HGP(H), where H is the parity-check matrix of the [6,3,3] code from Table I. HGP(\tilde{H}) and HGP(\tilde{H}^{(c)}) are constructed via applying classical weight reduction to H. [symbol] (H) is constructed by applying quantum weight reduction to HGP(H). As. Shown HGP(\tilde{H}) and HGP(\tilde{H}^{(c)}) have superior performance compared to the baseline code, whereas HGP(H) only achieves a comparable logical error rate for large values of

$${σ}^{2} / {σ}_{v a c}^{2} .$$

Thus, the codes obtained using the classical weight reduction method as described herein outperform the original code and the code obtained using the quantum weight reduction method. Even though the distance of the quantum weight-reduced code is the highest, the waterfall region (where the logical error rate starts to decrease) for this code begins at much higher values of

$${σ}^{2} / {σ}_{v a c}^{2}$$

when compared with the other codes. This is likely due to the increased row and column weights of the parity-check matrices.

The performance of two codes from Table II are also compared with their (compressed) weight-reduced counterparts. The results are shown in FIG. 18B. As may be observed, the weight reduced codes again have superior performance and it is further noted that the waterfall region for the weight-reduced codes begins at approximately

$${σ}^{2} / {σ}_{v a c}^{2} \approx 10.5 dB ,$$

compared with

$${σ}^{2} / {σ}_{v a c}^{2} \approx 11 dB$$

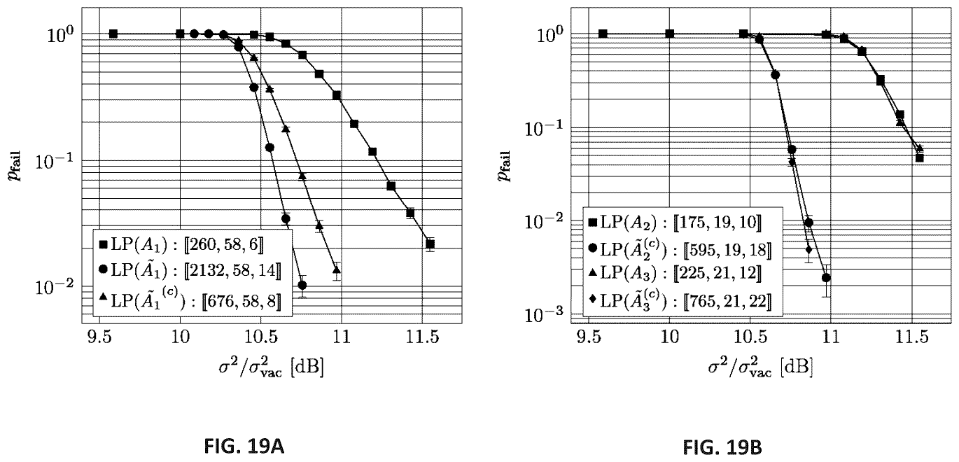

for the baseline codes, indicating that weight reduction not only improves logical error rates but also the breakeven point. Similar results hold for the lifted-product codes in shown in FIGS. 19A and 19B, which shows the simulation results for the lifted-product codes. In FIG. 19A the code LP(A₁) is compared with its weight reduced counterparts, LP(Ã₁) and

$$LP ( {\tilde{A}}_{1}^{( c )} )$$

as shown in the first row of Table IV. Again, performance improvement may be observed for the weight-reduced codes, with the uncompressed variant performing best. In FIG. 19B, the result of the comparison between the lifted-product codes from the second and the third rows of Table IV is shown. As in the hypergraph-product case, the waterfall region begins at a smaller value of

$${σ}^{2} / {σ}_{v a c}^{2}$$

for the weight-reduced codes.

### V. SUMMARIZING REMARKS

The construction of qLDPC codes with good performance under realistic noise models is an essential step toward designing more efficient fault-tolerant quantum computing architectures. Since the noise associated with measuring a stabilizer scales with both the row and column weight of the stabilizer matrix in many proposed architectures, qLDPC codes with lower weights are likely to have superior performance. Hastings has provided a method to reduce the weights of CSS codes but its use has so far been restricted to the asymptotic setting. Methods described in the present disclosure, at least in one aspect, provides an application of quantum weight reduction to codes constructed with near-term hardware in mind. In addition to the examples, the present disclosure has also provided an accessible review of the method with fewer mathematical prerequisites. Modifications to reduce the overhead has also been proposed and analyzed the effect of the method on iterative decoding.

In response to some of the drawbacks of the quantum weight reduction method, the present disclosure introduces classical and compressed classical weight reduction methods. Applying this technique to, e.g., the inputs of the hypergraph product may provide row weights of at most six and column weights at most three. We have shown that classical weight reduction can increase the distance of the classical code and hence the distance for the hypergraph-product code. The compressed variant may be capable of reducing the overhead while at least maintaining the distance of the input. The two approaches represent a trade-off between achieving the maximum reduction in overhead versus the maximum increase in distance. In another aspect, the present disclosure demonstrates permutations in weight reduction can increase both the distance and the girth of the Tanner graph. Classical weight reduction is applicable to quasi-cyclic codes defined by matrices with entries in a polynomial quotient ring, allowing the construction of examples of weight-reduced lifted-product codes with superior parameters to our hypergraph-product-code examples.

Both the quantum and classical weight reductions may have the same input and output code dimensions, but in at least some embodiments, the classical method as described herein uses far fewer qubits than the quantum method. Both may introduce long-range connectivity. An analysis of the cycle structure shows that quantum weight reduction may strongly degrade the performance of iterative decoders, while the classical case may improve it. The performances of the classically weight reduced codes based on embodiments of the present disclosure in a photonic quantum computing architecture based on GKP qubits and passive linear optics is benchmarked. Monte Carlo simulations is used to estimate the logical error rate of the foliated cluster state corresponding to a logical identity channel (quantum memory). In every simulation case, performance improvements have been observed for the codes produced using classical weight reduction in accordance with the present disclosure.

The results presented in the present disclosure show that weight-reduction techniques as described herein can be a useful tool for constructing useful qLDPC codes by transforming codes with good parameters but relatively high-weight checks into codes with low-weight checks, comparable parameters, and improved performance. It may be preferable to construct stabilizer codes with very low row and column weights and a high encoding rate and distance directly. It is suggested that optimizing the classical inputs to quantum product constructions may be a superior strategy to optimizing the output quantum code itself, which is perhaps not surprising given that the orthogonality constraints that restrict quantum codes do not apply in the classical case.

Although the present disclosure may be described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

1. A method of quantum error correction, comprising:
receiving a parity check matrix H of a classical code, the parity check matrix H having p rows and n columns, n and p being positive integers;
determining if a weight wᵣ of a row r of the p rows is above a target weight threshold x;
when the weight wᵣ is above the target weight threshold x, reducing the weight wᵣ by:
replacing the row r with a matrix M having m rows, m being a positive integer, the matrix M comprising of a first sub-matrix and a second sub-matrix, wherein:
the first sub-matrix comprises n columns, an i-th column of the first sub-matrix having a weight of 1 when an i-th element of the row r is 1, i being a positive integer, and the i-th column of the first sub-matrix having a weight of 0 when the i-th element of the row r is 0;
the second sub-matrix comprises (m−1) columns, each column of the (m−1) columns of the second sub-matrix having a non-zero even-numbered weight and each row of the m rows of the second sub-matrix having a weight of less than or equal to (x−w₁), w₁ being equal to the weight of a corresponding row of the first sub-matrix; and
appending (m−1) zeros to the end of each row of H that is not row r; and
performing quantum error correction based on the parity check matrix after the reducing.

2. The method of claim 1, further comprising, after the reducing and before the performing:
transposing the parity check matrix H;
repeating the determining and the reducing on the transposed parity check matrix; and
transposing the transposed parity check matrix.

3. The method of claim 1, further comprising replacing the row r with the matrix M when the weight wᵣ is greater than the weight threshold x.

4. The method of claim 1, wherein the determining and reducing are repeated for a plurality of rows of the parity check matrix before the performing.

5. The method of claim 1, wherein the classical code is a LDPC code.

6. The method of claim 1, wherein the weight threshold x is equal to 3.

7. The method of claim 1, wherein an i-th element of the i-th column of the first sub-matrix is 1 when the i-th element of the row r is 1.

8. The method of claim 1, wherein:
a first element of a first column of the first sub-matrix is 1;
an m-th element of an n-th column of the first sub-matrix is 1; and
an l-th element of an (l+1)-th column of the first sub-matrix is 1 when an (l+1)-th element of the row r is 1, l being a positive integer and l≤m.

9. The method of claim 1, further comprising permuting a plurality of non-zero columns of the first sub-matrix.

10. The method of claim 9, wherein the permuting further comprises determining a permutation of a plurality of permutations of the plurality of non-zero columns that provides optimal code parameters.

11. The method of claim 10, wherein the code parameters include code distance and encoding rate.

12. The method of claim 1, wherein:
a first element of a first row of the second sub-matrix is 1;
an (m−1)-th element of an m-th row of the second sub-matrix is 1;
for an integer j ranging from 2 to (m−1), when a j-th row of the first sub-matrix has a weight of 1, a k-th element and a (k+1)-th element of a j-th row of the second sub-matrix are each equal to 1, k being equal to a number of rows of the first sub-matrix above the j-th row with a weight of 1; and
when the j-th row of the first sub-matrix has a weight of 0, the j-th row of the second sub-matrix has a weight of 0.

13. A method of quantum error correction, comprising:
receiving a classical code comprising a first plurality checks and a first plurality of bits;
determining if a weight wₑ of a check c of the first plurality of checks is above a target weight threshold x;
when the weight w_{c} is above the target weight threshold x, reducing the weight w_{c} by replacing the check c with a second plurality of checks and adding a second plurality of bits to the classical code, wherein:
each bit of the first plurality of bits is in the support of a check of the second plurality of checks when the bit of the first plurality of bits is in the support of the check c,
each bit of the second plurality of bits is in the support of a non-zero even number of the second plurality of checks, and
each check of the second plurality of checks has support on x or fewer bits; and
performing quantum error correction based on the classical code after the reducing.

14. The method of claim 14, further comprising, after the reducing and before the performing:
transposing the first plurality of checks;
repeating the determining and the reducing on the transposed plurality of checks; and
transposing the transposed plurality of checks.

15. The method of claim 13, wherein the determining and reducing are repeated for each check in the first plurality of checks.

16. The method of claim 13, wherein the classical code is a LDPC code.

17. The method of claim 13, wherein the weight threshold x is equal to 3.

18. The method of claim 13, further comprising permuting a plurality of non-zero columns of the first plurality of checks.

19. The method of claim 18, wherein the permuting further comprises determining a permutation of a plurality of permutations of the plurality of non-zero columns that provides optimal code parameters.

20. The method of claim 19, wherein the code parameters include code distance and encoding rate.
